(19) United States
(12) Patent Application Publication
(10) Pub. No.: US 2023/0195002 A1
(43) Pub. Date: Jun. 22, 2023

(54) EXPOSURE DEVICE AND METHOD FOR MANUFACTURING SEMICONDUCTOR DEVICE

(71) Applicant: KIOXIA CORPORATION, Tokyo (JP)

(72) Inventor: Yoshio MIZUTA, Yokkaichi Mie (JP)

(21) Appl. No.: 17/901,774

(22) Filed: Sep. 1, 2022

(30) Foreign Application Priority Data
Dec. 16, 2021 (JP) 2021-204292

(51) Int. Cl. G03F 9/00

(52) U.S. Cl. CPC G03F 9/7088; G03F 9/7046

(57) ABSTRACT

According to one embodiment, an exposure device includes a stage, a measurement device, and a control device. For exposing a substrate, the control device calculates a first coefficient corresponding to a magnification positional misalignment in a first direction and a second coefficient corresponding to a magnification positional misalignment in a second direction based on measurement of at least three alignment marks. The control device can use the first coefficient to correct the magnification positional misalignment in the first direction and a third coefficient set based on the first correction coefficient to correct the magnification positional misalignment in the second direction. The control device can use a fourth coefficient set based on the second coefficient to correct the magnification positional misalignment in the first direction and the second coefficient to correct the magnification positional misalignment in the second direction.

### CROSS-REFERENCE TO RELATED APPLICATION(S)

This application is based upon and claims the benefit of priority from Japanese Patent Application No. 2021-204292, filed Dec. 16, 2021, the entire contents of which are incorporated herein by reference.

### FIELD

Embodiments described herein relate generally to an exposure device and a method for manufacturing a semiconductor device.

### BACKGROUND

In general, a three-dimensional stacking technique for stacking semiconductor circuit boards for manufacture of semiconductor devices is known.

### BRIEF DESCRIPTION OF THE DRAWINGS

FIG. 1 is a schematic diagram showing an overview of a method for manufacturing a semiconductor device.

FIGS. 2A to 2J are schematic diagrams showing examples of superposition misalignment components that may occur in a step of manufacturing a semiconductor device.

FIGS. 3A to 3C are schematic diagrams of alignment marks used in a step of manufacturing a semiconductor device.

FIG. 4 is a table showing an example of the correction performance of the superposition misalignment components in a wafer surface in an exposure device and a bonding device.

FIG. 5 is a block diagram of an exposure device according to a first embodiment.

FIG. 6 is a flowchart of an exposure process according to a first embodiment.

FIG. 7 is a table showing an example of an exposure recipe used in a first embodiment.

FIG. 8 is a schematic diagram showing an example of a change in superposition misalignment of a wafer magnification when alignment correction in a normal mode is used.

FIG. 9 is a schematic diagram showing an example of a change in superposition misalignment of a wafer magnification when alignment correction in the normal mode is used.

FIG. 10 is a schematic diagram showing an example of a change in superposition misalignment of a wafer magnification when alignment correction in an X-oriented mode is used.

FIG. 11 is a schematic diagram showing an example of a change in superposition misalignment of a wafer magnification when alignment correction in a Y-oriented mode is used.

FIG. 12 is a schematic diagram showing an example of a change in superposition misalignment of wafer orthogonality when alignment correction in a normal mode is used.

FIG. 13 is a schematic diagram showing an example of a change in superposition misalignment of wafer orthogonality when alignment correction in a normal mode is used.

FIG. 14 is a schematic diagram showing an example of a change in superposition misalignment of wafer orthogonality when alignment correction of a X-oriented mode is used.

FIG. 15 is a schematic diagram showing an example of a change in superposition misalignment of wafer orthogonality when alignment correction of a Y-oriented mode is used.

FIG. 16 is a block diagram showing an example of a configuration of a semiconductor manufacturing system according to a second embodiment.

FIG. 17 is a block diagram showing an example of a configuration of a bonding device according to a second embodiment.

FIG. 18 is a block diagram showing an example of a configuration of a server according to a second embodiment.

FIG. 19 is a schematic diagram showing an overview of a bonding process of a bonding device according to a second embodiment.

FIG. 20 is a flowchart related to correction of wafer magnification in a bonding process of a bonding device according to a second embodiment.

FIG. 21 is a flowchart related to correction of wafer magnification in a bonding process of a bonding device according to a modified example of a second embodiment.

FIG. 22 is a flowchart of a method of creating a superposition misalignment correction formula used in a bonding device according to a third embodiment.

FIG. 23 is a flowchart of a bonding process of a bonding device according to a third embodiment.

FIG. 24 is a schematic diagram showing an example of a plurality of wafers used for creating a superposition misalignment correction formula used in a bonding device according to a third embodiment.

FIGS. 25A and 25B are graphs showing examples of a change in the amount of deception of the shift measurement before and after creating the superposition misalignment correction formula in the bonding process of the bonding device according to the third embodiment.

FIG. 26 is a block diagram of a memory device according to a fourth embodiment.

FIG. 27 is a circuit diagram of a memory cell array in a memory device according to a fourth embodiment.

FIG. 28 depicts aspect of a structure of a memory device according to a fourth embodiment.

FIG. 29 depicts a plan view layout of a memory cell array in a memory device according to a fourth embodiment.

FIG. 30 depicts a cross-sectional structure of a memory cell array provided in a memory device according to a fourth embodiment.

FIG. 31 depicts a cross-sectional structure of a memory pillar in a memory device according to a fourth embodiment.

FIG. 32 depicts a cross-sectional structure of a memory device according to a fourth embodiment.

### DETAILED DESCRIPTION

Certain embodiments provide improved manufacturing yield of semiconductor devices.

In general, according to one embodiment, an exposure can expose a substrate with illumination light via a projection optical system. The exposure device includes a stage, a measurement device, and a control device. The stage holds the substrate. The measurement device measures at least three alignment marks of the substrate. In this context, “measures” means obtaining positional coordinates or the like. The control device moves the stage based on measurement of the measurement device to control an exposure position for the substrate. In the exposure process of the substrate, the control device calculates each of a first correction coefficient corresponding to a positional misalignment of a magnification component in a first direction and a second correction coefficient corresponding to a positional misalignment of a magnification component in a second direction intersecting the first direction, based on measurement of the at least three alignment marks. When a first setting is applied, the control device uses the first correction coefficient to correct the positional misalignment of the magnification component in the first direction and a third correction coefficient based on the first correction coefficient to correct the positional misalignment of the magnification component in the second direction. When a second setting is applied, the control device uses a fourth correction coefficient based on the second correction coefficient to correct the positional misalignment of the magnification component in the first direction and the second correction coefficient to correct the positional misalignment of the magnification component in the second direction.

Hereinafter, certain example embodiments will be described with reference to the drawings. Each example embodiment illustrates a device or a method for embodying certain technical concepts of the present disclosure and are non-limiting. The drawings are schematic or conceptual. The dimensions and ratios of each drawing are not necessarily the same as the actual ones of a device or apparatus. In some instances, certain details or aspects of a configuration are not shown in the drawings. The hatching in certain drawings is not necessarily related to the materials and/or properties of the components having such hatching in the drawings and may be provided to permit distinguishing of the positioning of different components being described. In the present specification, the same reference numerals are used for those components having substantially the same function and configuration as one another.

A semiconductor device in the present specification is formed by bonding two substrates to one another. On each substrate semiconductor circuits or portions thereof are formed. The joined semiconductor substrates are subsequently singulated (e.g., diced) into separate chips or the like. In the following examples, each substrate is referred to as a “wafer” but in other examples the substrate may be something other than a wafer, such as a sub-portion of wafer, a circuit board, or the like. A process of bonding two wafers is called a “bonding process”. A device that executes the bonding process is called a “bonding device”. The wafer disposed on an upper side during the bonding process is called an “upper wafer UW”. The wafer disposed on a lower side during the bonding process is called a “lower wafer LW”. The set of the two bonded wafers, that is, the upper wafer UW and the lower wafer LW, is referred to as a “bonded wafer BW”. In the present specification, an X direction and a Y direction are directions that intersect each other and are directions that are parallel to a surface of the wafer. A Z direction is a direction that intersects each of the X direction and the Y direction, and is a direction perpendicular to the surface of the wafer. The “surface of the wafer” is a surface on which a semiconductor circuit is formed. A “back surface of the wafer” is a side opposite to this surface of the wafer. As used herein, “up” and “down” directions are defined based on the Z direction.

### Overview of Method for Manufacturing Semiconductor Device

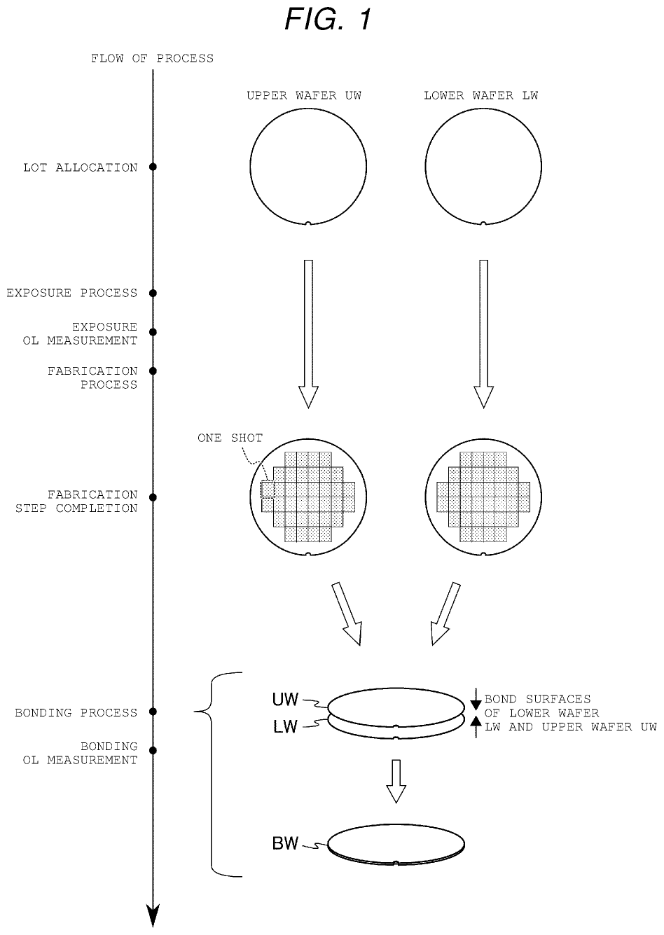

FIG. 1 is a schematic diagram showing an outline of a method for manufacturing a semiconductor device. The flow of the general process for manufacturing a semiconductor device according to the present specification will be described with reference to FIG. 1.

First, wafers are allocated to different lots (“lot allocation”). Each lot is classified into, for example, a lot including the upper wafer UW (a UW lot) and a lot including the lower wafer LW (a LW lot). Steps are carried out separately on each lot, and a semiconductor circuit is formed on each of the upper wafers UW and the lower wafers LW. The steps for fabricating the semiconductor circuits generally comprise a combination of an “exposure process”, an “exposure overlay (OL) measurement” and an “fabrication process”.

The exposure process is, for example, a lithographic process of transferring a mask pattern to the wafer by exposing the wafer coated with the resist to light transmitted through a mask including the mask pattern therein or thereon. A region where the mask pattern is transferred by one exposure corresponds to “one shot region”. In the exposure process, one shot of exposure is repeatedly executed while shifting an exposure position. That is, the exposure process is executed by a step-and-repeat method. In the exposure process, the disposition and shape of each shot can be corrected (adjusted) based on the measurement results of the alignment marks on the wafer or the like, and the superposition position with a pattern previously formed on the wafer (an underlying pattern) can be adjusted (aligned). The disposition (layout) of a plurality of shots on the upper wafer UW and the disposition (layout) of a plurality of shots on the lower wafer LW are set to be the same. Hereinafter, a device that executes the exposure process is referred to as an “exposure device”.

The exposure OL measurement is a process of measuring the amount of superposition misalignment between the pattern formed by the exposure process and the pattern already formed on the wafer before the exposure process. The measurement result of the amount of superposition misalignment obtained by the exposure OL measurement is used for a rework determination of the exposure process, calculation of a superposition misalignment correction value applied to a subsequent lot, and the like. The fabrication process is, for example, an etching process by which the wafer is selectively etched by using a resist mask formed on the wafer by the exposure process. When the fabrication process is completed, the resist mask or the like can be removed and another step executed.

When the various circuit fabrication steps are completed, the bonding process is executed. In the bonding process, the primary surface of the upper wafer UW and the primary surface of the lower wafer LW face each other in the bonding device. Then, in the bonding process, the superposition position of a pattern formed on the primary surface of the upper wafer UW and a pattern formed on the primary surface of the lower wafer LW is adjusted (aligned). Then, the bonding device joins surfaces of the upper wafer UW and the lower wafer LW to each other to form a bonded wafer BW.

On the bonded wafer BW formed by the bonding process, the bonding overlay (OL) measurement is executed. The bonding OL measurement is a process of measuring the amount of superposition misalignment between a pattern formed on the surface of the upper wafer UW and a pattern formed on the surface of the lower wafer LW. The measured amount of superposition misalignment obtained in the bonding OL measurement is used for calculating a superposition misalignment correction value that can be applied to the exposure process of a subsequent lot.

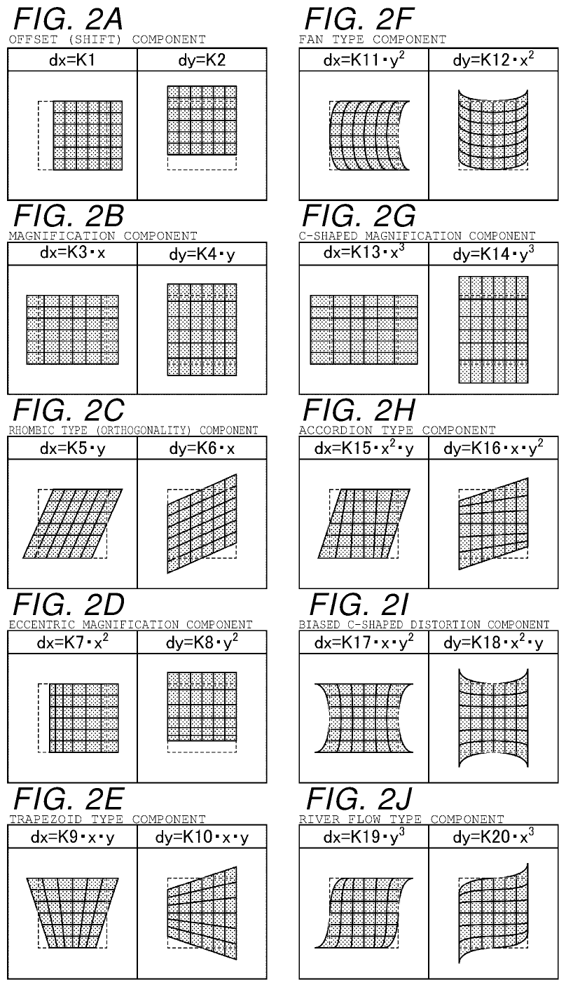

The amount of superposition misalignment occurring in the exposure process and the bonding process can be expressed as a combination of various components. FIGS. 2A to 2J are schematic diagrams showing examples of superposition misalignment components that may occur in a step of manufacturing a semiconductor device. FIGS. 2A to 2J illustrate mathematical formulas corresponding to the respective superposition misalignment components and changes in the shape of one shot based on the mathematical formulas. As shown in FIGS. 2A to 2J, the superposition misalignment components include, for example, an offset component of FIG. 2A, a magnification component of FIG. 2B, a rhombic type (orthogonality) component of FIG. 2C, an eccentric magnification component of FIG. 2D, a trapezoid type component of FIG. 2E, a fan type component of FIG. 2F, a C-shaped magnification component of FIG. 2G, an accordion type component of FIG. 2H, a biased C-shaped distortion component of FIG. 2I, and a river flow type component of FIG. 2J. The superposition misalignment component in each of FIGS. 2A to 2J, further includes components in the X direction and the Y direction.

The mathematical formulas corresponding to the respective components in FIGS. 2A to 2J are listed below. In the following mathematical formulas, “x” and “y” correspond to a coordinate in the X direction (X coordinate) and a coordinate in the Y direction (Y coordinate), respectively. The terms “dx” and “dy” are for the amount of superposition misalignment in the X direction and the amount of superposition misalignment in the Y direction, respectively. The terms “K1” to “K20” are coefficients of the respective superposition misalignment components, respectively.

In FIG. 2A, the offset (shift) component in the X direction is “dx=K1”. The offset (shift) component in the Y direction is “dy=K2”.

In FIG. 2B, the magnification component in the X direction is “dx=K3·x”. The magnification component in the Y direction is “dy=K4·y”.

In FIG. 2C, the rhombic type (orthogonality) component in the X direction is “dx=K5·y”. The rhombic type (orthogonality) component in the Y direction is “dy=K6·x”.

In FIG. 2D, the eccentric magnification component in the X direction is “dx=K7·x²”. The eccentric magnification component in the Y direction is “dy=K8·y²”.

In FIG. 2E, the trapezoid type component in the X direction is “dx=K9·x·y”. The trapezoid type component in the Y direction is “dy=K10·x·y”.

In FIG. 2F, the fan type component in the X direction is “dx=K11·y²”. The fan type component in the Y direction is “dy=K12·x²”.

In FIG. 2G, the C-shaped magnification component in the X direction is “dx=K13·x³”. The C-shaped magnification component in the Y direction is “dy=K14·y³”.

In FIG. 2H, the accordion type component in the X direction is “dx=K15·x²·y”. The accordion type component in the Y direction is “dy=K16·x·y²”.

In FIG. 2I, the C-shaped distortion component in the X direction is “dx=K17·x·y²”. The C-shaped distortion component in the Y direction is “dy=K18·x²·y”.

In FIG. 2J, the river flow type component in the X direction is “dx=K19·y³”. The river flow type component in the Y direction is “dy=K20·x³”.

Although FIGS. 2A to 2J illustrate the superposition misalignment components across multiple shot units, the superposition misalignment components occurring in the plane of the wafer can also be expressed as the superposition misalignment components within the same shot unit. Hereinafter, the superposition misalignment of the magnification component occurring in the plane of the wafer is also referred to as “wafer magnification”. The superposition misalignment of the orthogonality component occurring in the plane of the wafer is also referred to as “wafer orthogonality”. Each of the exposure device and the bonding device uses the measurement results of the alignment marks formed on the wafer for the alignment.

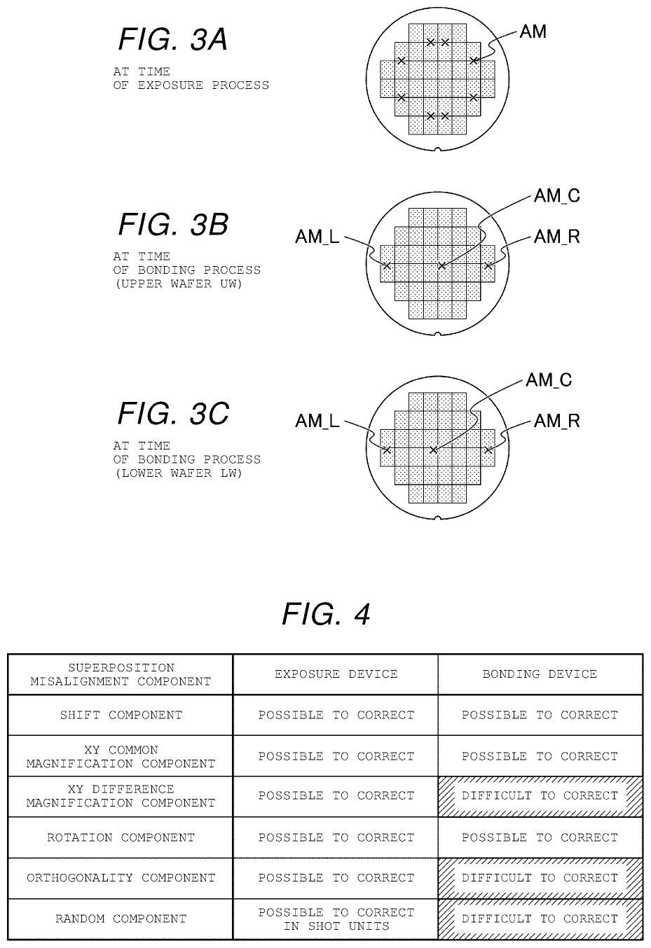

FIGS. 3A to 3C are schematic diagrams showing examples of the dispositions of alignment marks used in the step of manufacturing the semiconductor device. FIG. 3A illustrates the positions of alignment marks AM measured at the time of the exposure process. FIG. 3B illustrates the positions of the alignment marks AM of the upper wafer UW measured at the time of the bonding process. FIG. 3C illustrates the positions of the alignment marks AM of the lower wafer LW measured at the time of the bonding process.

As shown in FIG. 3A, the exposure device can measure the alignment marks AM at multiple points (at least three or more points) disposed on the wafer at the time of the exposure process. Then, the exposure device performs function approximation on the measured results for the alignment marks AM at the multiple points in an orthogonal coordinate system, and can calculate the correction values of the superposition misalignment components such as a shift component, a magnification component, and an orthogonality component in each of the X direction and the Y direction. Furthermore, the exposure device can generally correct each of the superposition misalignment components in shot units and the superposition misalignment components in the plane of the wafer. In this way, the exposure device can correct complicated superposition misalignment components.

As shown in FIGS. 3B and 3C, the bonding device measures at least three alignment marks AM_C, AM_L, and AM_R disposed on each of the upper wafer WU and the lower wafer LW at the time of the bonding process. The alignment mark AM_C is disposed near the center of the wafer. The bonding device uses the measurement result of the alignment mark AM_C for the alignment of the shift component of the wafer. The alignment marks AM_L and AM_R are disposed on one side and the other side of the outer circumference of the wafer, respectively. The bonding device uses the measurement results of the alignment marks AM_L and AM_R for the alignment of the rotation component of the wafer.

In this way, the bonding device can calculate the correction values of the simple superposition misalignment components (the shift component and the rotation component) in the wafer surface by using at least three alignment marks AM_C, AM_L and AM_R. The bonding device may measure the alignment mark AM of each of the upper wafer UW and the lower wafer LW in parallel (at the same time). For example, the alignment mark AM_C of each of the upper wafer UW and the lower wafer LW is measured at the same time due to the limitation of the disposition of the alignment mark AM, thereby being disposed so as to be offset from the center of the wafer in opposite directions.

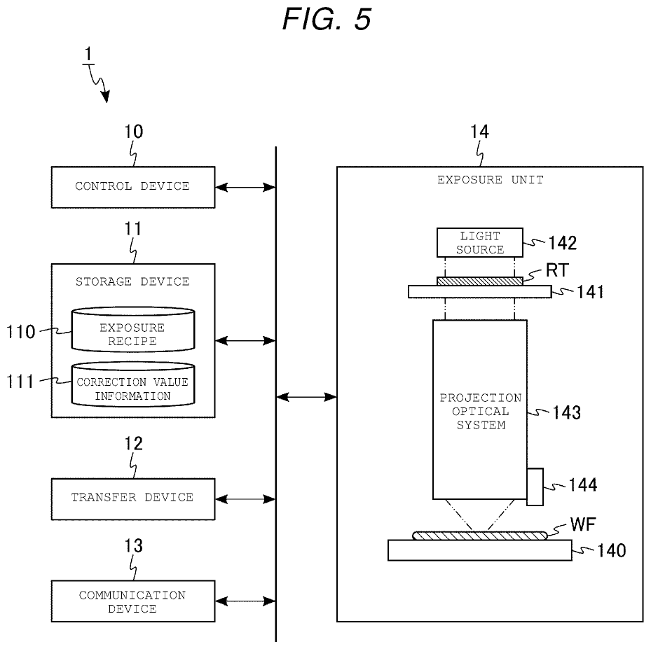

FIG. 4 is a table showing an example of the correction performance of the superposition misalignment components in the exposure device and the bonding device. As shown in FIG. 4, the shift component can be corrected by both the exposure device and the bonding device. The wafer magnification common to the X direction and the Y direction (XY common magnification component) can be corrected by both the exposure device and the bonding device. A method for correcting the XY common magnification component in the bonding device will be described later. The wafer magnification (XY difference magnification component) having a difference in the X direction and the Y direction can be corrected by the exposure device. On the other hand, the XY difference magnification component is difficult to correct in the bonding device. The rotation component can be corrected by both the exposure device and the bonding device. The rotation component (orthogonality component) having a difference in the X direction and the Y direction can be corrected by the exposure device. On the other hand, the orthogonality component is difficult to correct in the bonding device. The superposition misalignment component (random component) randomly occurring in the wafer surface can be corrected in shot units in the exposure device. On the other hand, the random component is difficult to correct in the bonding device.

### [1] First Embodiment

A first embodiment relates to an exposure device in which the alignment correction setting in a specific step of the fabrication process of the lower wafer LW can be changed according to the design of the semiconductor device.

### [1-1] Configuration of Exposure Device 1

FIG. 5 is a block diagram showing an example of the configuration of the exposure device 1 according to the first embodiment. As shown in FIG. 5, the exposure device 1 includes a control device 10, a storage device 11, a transfer device 12, a communication device 13, and an exposure unit 14.

The control device 10 is a computer or the like that controls the overall operation of the exposure device 1. The control device 10 controls each of the storage device 11, the transfer device 12, the communication device 13, and the exposure unit 14. The control device 10 includes a Central Processing Unit (CPU), a Read Only Memory (ROM), a Random Access Memory (RAM), and the like. The CPU is a processor that executes various programs related to the control of the device. The ROM is a non-volatile storage medium that stores a control program for the device. The RAM is a volatile storage medium used as a work area for the CPU.

The storage device 11 is a storage medium used for storing data, programs, and the like. The storage device 11 stores, for example, exposure recipe 110 and correction value information 111. The exposure recipe 110 is a table in which setting of the exposure process is recorded. The exposure recipe 110 includes information such as the shape and layout of the shot, an exposure amount, focus setting, and alignment setting. The exposure recipe 110 may be prepared for each processing step or each processing lot. The correction value information 111 is a log for recording the correction value(s) (that is, an alignment result) of the superposition misalignment used when the exposure process is executed.

The transfer device 12 includes a transfer arm capable of transferring the wafer, a transition position for temporarily placing a plurality of wafers, and the like. For example, the transfer device 12 transfers the wafer WF received from, for example, an external coating and developing device to the exposure unit 14. Furthermore, the transfer device 12 transfers the wafer WF received from the exposure unit 14 to the outside of the exposure device 1 after the exposure process has been completed. The “coating and developing device” in this context is a device that executes pre-processing steps before the exposure process and/or post-processing steps after the exposure process. The pre-processing of the exposure process includes a process of applying a resist material (photosensitive material) to the wafer. The post-processing of the exposure process includes a process of developing a pattern exposed on the wafer. A plurality of semiconductor manufacturing devices may be used for the pre-processing and the post-processing.

The communication device 13 is a communication interface that can be connected to a network. The exposure device 1 may operate based on an operation by a terminal on the network, or may store the exposure recipe 110 and the correction value information 111 in a server on the network.

The exposure unit 14 is a set of configurations used in the exposure process. The exposure unit 14 includes, for example, a wafer stage 140, a reticle stage 141, a light source 142, a projection optical system 143, and a camera 144. The wafer stage 140 has a function of holding the wafer WF. The reticle stage 141 has a function of holding a reticle RT (photomask). The respective stage positions of the wafer stage 140 and the reticle stage 141 can be controlled based on the control of the control device 10. The light source 142 irradiates the reticle RT with the generated light. The projection optical system 143 collects light transmitted through the reticle RT on the surface of the wafer WF. The camera 144 is an imaging mechanism used for measuring the alignment mark AM.

### [1-2] Method for Manufacturing Semiconductor Device

Hereinafter, an example of a specific process using the exposure device 1 in a method for manufacturing a semiconductor device according to the first embodiment will be described. That is, the semiconductor device is manufactured by using an exposure method (exposure process) of the first embodiment described below.

### [1-2-1] Exposure Process

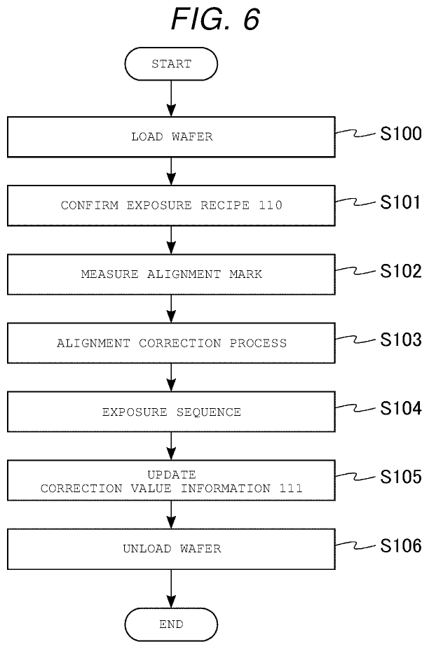

FIG. 6 is a flowchart showing an example of the exposure process of the exposure device 1 according to the first embodiment.

The exposure device 1 starts the exposure process when the coating and developing device notifies that the pre-processing of the wafer is completed (start).

First, the exposure device 1 loads the wafer (S100). The wafer loaded from the coating and developing device is held by the wafer stage 140.

Next, the exposure device 1 confirms the exposure recipe 110 (S101). As a result, the control device 10 determines processing conditions to be applied to the loaded wafer.

Next, the exposure device 1 measures the alignment marks AM (S102). Specifically, the camera 144 images a plurality of alignment marks AM disposed at predetermined positions on the wafer.

Next, the exposure device 1 executes an alignment correction process (S103). Specifically, the control device 10 calculates correction values such as a shot disposition and a shot shape to be exposed on the wafer based on shooting results of the plurality of alignment marks AM.

Next, the exposure device 1 executes an exposure sequence (S104). Specifically, the control device 10 controls the light source 142, the wafer stage 140, and the reticle stage 141 based on the correction value calculated in S103, and irradiates the wafer with the light transmitted through the mask in a step-and-repeat manner.

Next, the exposure device 1 updates the correction value information 111 (S105). That is, in S105, the correction value calculated in S103 is associated with the processed wafer and recorded in the correction value information 111.

Next, the exposure device 1 unloads the wafer (S106). The unloaded wafer is passed to the coating and developing device. The coating and developing device executes heat treatment, development, cleaning, and the like on the wafer on which the exposure process is completed. As a result, a pattern is formed on the wafer.

When the wafer is unloaded, the exposure device 1 ends the exposure process (end).

### [1-2-2] Specific Example of Exposure Recipe

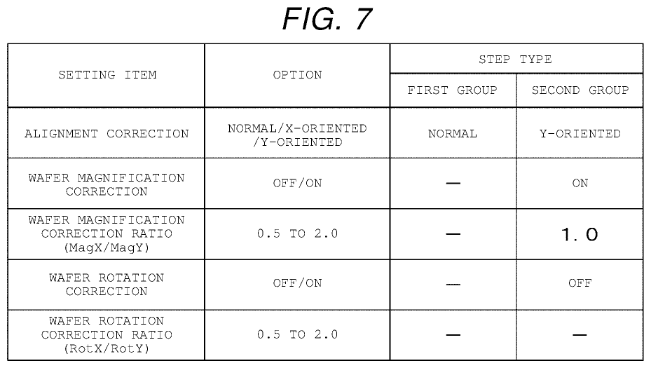

FIG. 7 is a table showing an example of the exposure recipe 110 used in the exposure device 1 according to the first embodiment. As shown in FIG. 7, the exposure recipe 110 stores a setting item, an option, and a step type in association with each other. The setting item of the exposure recipe 110 includes, for example, “alignment correction”, “wafer magnification correction”, “wafer magnification correction ratio (MagX/MagY)”, “wafer rotation correction”, and “wafer rotation correction ratio (RotX/RotY)”.

The option for setting of the alignment correction includes “normal (mode)”, “X-oriented (mode)”, and “Y-oriented (mode)”. The normal mode is setting in which the exposure process is executed by applying a correction of approximately 100% to each of the superposition misalignment components in the X direction and the Y direction. The X-oriented mode is a setting in which the exposure process is executed while orienting the correction of the superposition misalignment component in the X direction. Specifically, in the X-oriented mode, a correction of approximately 100% is applied to the superposition misalignment component in the X direction with respect to the alignment result. On the other hand, in the X-oriented mode, the correction based on the correction ratio with respect to the correction value in the X direction is applied to the superposition misalignment component in the Y direction. The Y-oriented mode is a setting in which the exposure process is executed with priority given to the correction of the superposition misalignment component in the Y direction. Specifically, in the Y-oriented mode, a correction of approximately 100% is applied to the superposition misalignment component in the Y direction with respect to the alignment result. On the other hand, in the Y-oriented mode, the correction based on the correction ratio with respect to the correction value in the Y direction is applied to the superposition misalignment component in the X direction.

The option for setting of the wafer magnification correction includes “off” and “on”. When the setting of the wafer magnification correction is “off”, the exposure device 1 applies the condition of the normal mode to the calculation of the correction value of the wafer magnification in the exposure process. When the setting of the wafer magnification correction is “on”, the exposure device 1 applies the condition of the X-oriented mode or the Y-oriented mode to the calculation of the correction value of the wafer magnification in the exposure process. Further, when the setting of the wafer magnification correction is “on”, the setting of the wafer magnification correction ratio is referred to. The setting of the wafer magnification correction ratio indicates the ratio (MagX/MagY) of the correction value (MagX) of the wafer magnification in the X direction and the correction value (MagY) of the wafer magnification in the Y direction in the alignment correction. The wafer magnification correction ratio is set, for example, in the range of 0.5 to 2.0. When MagX/MagY=1, the exposure device 1 sets MagX:MagY of the exposure device reference to 1:1.

The option for setting the wafer rotation correction includes “off” and “on”. When the setting of the wafer rotation correction is “off”, the exposure device 1 applies the condition of the normal mode to the calculation of the correction value of the wafer rotation component in the exposure process. When the setting of the wafer rotation correction is “on”, the exposure device 1 applies the condition of the X-oriented mode or the Y-oriented mode to the calculation of the correction value of the wafer rotation component in the exposure process. Further, when the setting of the wafer rotation correction is “on”, the setting of the wafer rotation correction ratio is referred to. The setting of the wafer rotation correction ratio indicates the ratio (RotX/RotY) of the correction value (RotX) of the wafer orthogonality in the X direction and the correction value (RotY) of the wafer orthogonality in the Y direction in the alignment correction. The wafer rotation correction ratio is set, for example, in the range of 0.5 to 2.0. When RotX/RotY=1, the exposure device 1 sets RotX:RotY of the exposure device reference to 1:1.

The step type is, for example, a parameter allocated to each processing step of the exposure device. The step type includes, for example, a first group and a second group. The processing step of the first group is allocated to, for example, the exposure process of a first half. The processing step of the second group is allocated to, for example, the exposure process for forming a wiring layer near the wafer surface. For the first group, for example, a normal mode is used as the setting of the alignment correction. For the second group, for example, the Y-oriented mode is used as the setting of the alignment correction. Further, in the second group, for example, the setting of the wafer magnification correction is set to “on”, the wafer magnification correction ratio is set to “1”, and the setting of the wafer rotation correction is set to “off”. As described above, when either the X-oriented mode or the Y-oriented mode is used, at least one of the wafer magnification correction and the wafer rotation correction may be used. By editing the exposure recipe 110, the user may change parameters, such as the use of the X-oriented mode or the Y-oriented mode, of the alignment correction for each processing lot.

### [1-2-3] Specific Example of Alignment Correction Process

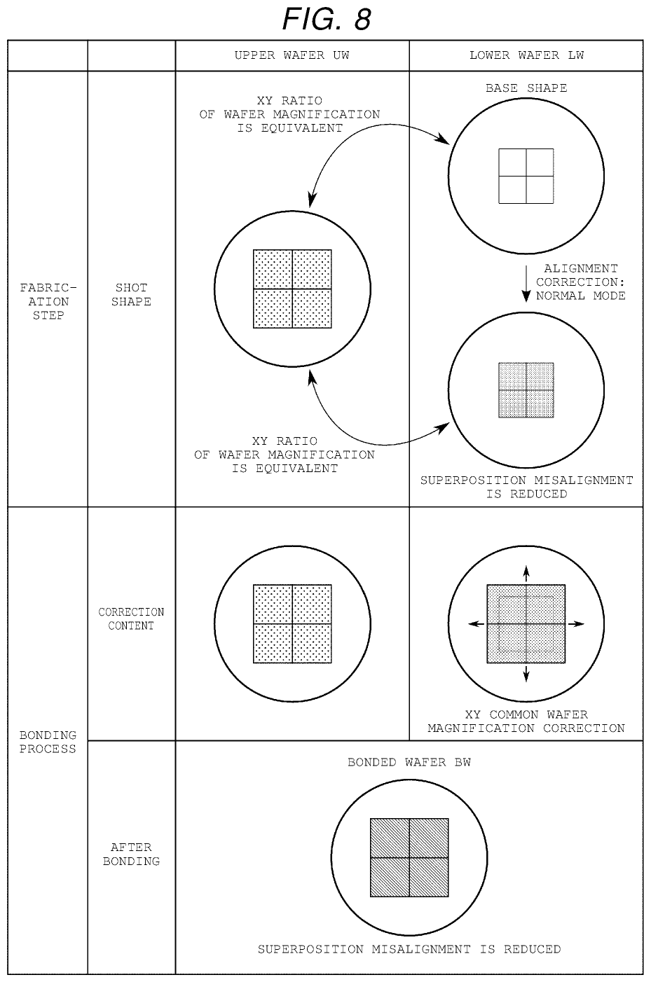

Certain specific examples of the alignment correction process will be described with reference to FIGS. 8 to 15. FIGS. 8 to 15 schematically show the shot shape of the upper wafer UW, the shot shape of the lower wafer LW before and after an exposure process, the content of the alignment correction used in the bonding process, and the state of superposition of the bonded wafer BW after bonding. The shot shape shown in the drawing illustrates the shape of a set of a plurality of shots disposed on the wafer surface, and schematically shows a state in which the influence of variations in such things as wafer magnification and wafer orthogonality occurs at the wafer surface. Hereinafter, the alignment correction process will be described focusing on the issues of wafer magnification and wafer orthogonality, but, in the actual exposure process, the alignment result may be reflected in both the superposition misalignment component (shot component) in shot unit and the superposition misalignment component (wafer component) in plane of the wafer.

FIG. 8 is a schematic diagram showing an example of a change in the superposition misalignment of the wafer magnification when the alignment correction in the normal mode is used in the step of manufacturing the semiconductor device according to the first embodiment. As shown in FIG. 8, an XY ratio of the wafer magnification of the lower wafer LW in this example is equivalent to an XY ratio of the wafer magnification of the base shape of the upper wafer UW. In this example, since the alignment correction setting is the normal mode, the shot shape to which the wafer component correction is applied by the exposure process is corrected to be substantially the same as the base shape. Therefore, in the exposure process of the lower wafer LW, the occurrence of the superposition misalignment of the wafer magnification is reduced. The XY ratio of the wafer magnification of the lower wafer LW after the exposure process is equivalent to the XY ratio of the wafer magnification of the upper wafer UW. After that, the bonding device applies the XY common wafer magnification correction to the lower wafer LW to execute the bonding process. In this example, since the XY ratios of the wafer magnifications of the upper wafer UW and the lower wafer LW at the time of the bonding process are equivalent to each other, the superposition misalignment between the wafer magnifications of the upper wafer UW and the lower wafer LW in the bonded wafer BW is reduced.

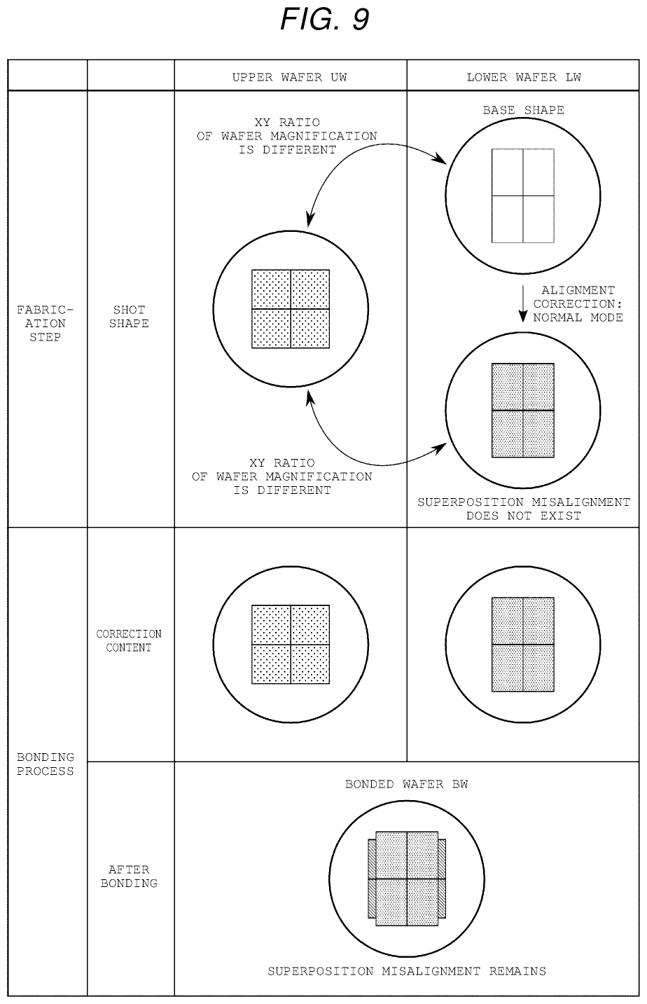

FIG. 9 is a schematic diagram showing an example of the change in the superposition misalignment of the wafer magnification when the alignment correction in the normal mode is used in the step of manufacturing the semiconductor device according to the first embodiment. As shown in FIG. 9, the XY ratio of the wafer magnification of the lower wafer LW in this example is different from the XY ratio of the wafer magnification of the base shape of the upper wafer UW. In this example, since the alignment correction setting is the normal mode, the shot shape to which the wafer component correction is applied by the exposure process is corrected to be substantially the same as the base shape. Therefore, in the exposure process of the lower wafer LW, the occurrence of the superposition misalignment of the wafer magnification is reduced. The XY ratio of the wafer magnification of the lower wafer LW after the exposure process is different from the XY ratio of the wafer magnification of the upper wafer UW. After that, the bonding device applies the XY common wafer magnification correction to the lower wafer LW to execute the bonding process. In this example, the XY ratios of the wafer magnifications of the upper wafer UW and the lower wafer LW at the time of the bonding process are different from each other, and the bonding device may not correct the XY difference in the wafer magnifications, so that the superposition misalignment between the wafer magnifications of the upper wafer UW and the lower wafer LW in the bonded wafer BW remains.

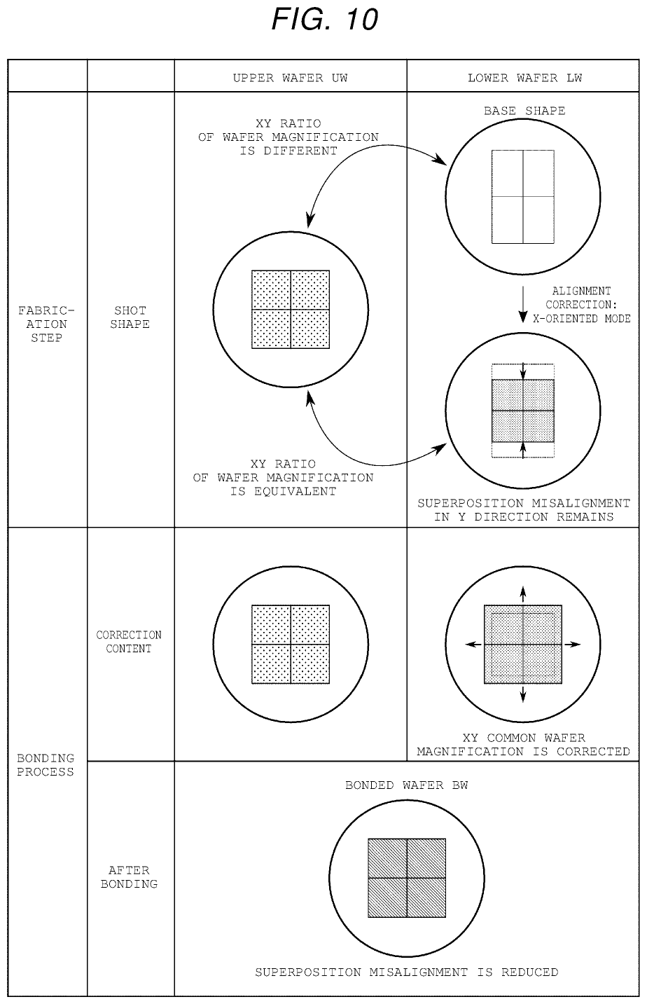

FIG. 10 is a schematic diagram showing an example of a change in the superposition misalignment of the wafer magnification when the alignment correction in the X-oriented mode is used in the step of manufacturing the semiconductor device according to the first embodiment. As shown in FIG. 10, the XY ratio of the wafer magnification of the lower wafer LW in this example is different from the XY ratio of the wafer magnification of the upper wafer UW. In this example, since the alignment correction setting is the X-oriented mode, the wafer magnification applied to the correction of the wafer component in the exposure process is equivalent to the XY ratio of the wafer magnification of the upper wafer UW, and the superposition misalignment with the base shape is reduced only in the X direction. Therefore, in the exposure process of the lower wafer LW, the occurrence of the superposition misalignment of the wafer magnification in the X direction is reduced, and the superposition misalignment of the wafer magnification in the Y direction remains. After that, the bonding device applies the XY common wafer magnification correction to the lower wafer LW to execute the bonding process. In this example, since the XY ratios of the wafer magnifications of the upper wafer UW and the lower wafer LW at the time of the bonding process are equivalent to each other, the superposition misalignment between the wafer magnifications of the upper wafer UW and the lower wafer LW in the bonded wafer BW is reduced.

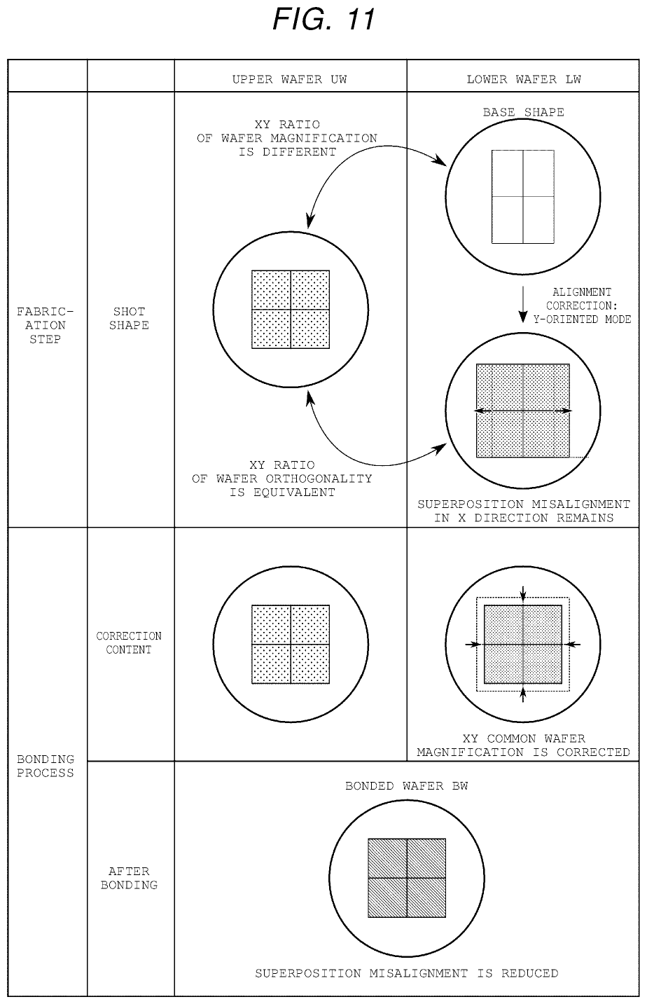

FIG. 11 is a schematic diagram showing an example of a change in the superposition misalignment of the wafer magnification when the alignment correction in the Y-oriented mode is used in the step of manufacturing the semiconductor device according to the first embodiment. As shown in FIG. 11, the XY ratio of the wafer magnification of the lower wafer LW in this example is different from the XY ratio of the wafer magnification of the upper wafer UW. In this example, since the alignment correction setting is the Y-oriented mode, the wafer magnification applied to the correction of the wafer component in the exposure process is equivalent to the XY ratio of the wafer magnification of the upper wafer UW, and the superposition misalignment with the base shape is reduced only in the Y direction. Therefore, in the exposure process of the lower wafer LW, the occurrence of the superposition misalignment of the wafer magnification in the Y direction is reduced, and the superposition misalignment of the wafer magnification in the X direction remains. After that, the bonding device applies the XY common wafer magnification correction to the lower wafer LW to execute the bonding process. In this example, since the XY ratios of the wafer magnifications of the upper wafer UW and the lower wafer LW at the time of the bonding process are equivalent to each other, the superposition misalignment between the wafer magnifications of the upper wafer UW and the lower wafer LW in the bonded wafer BW is reduced.

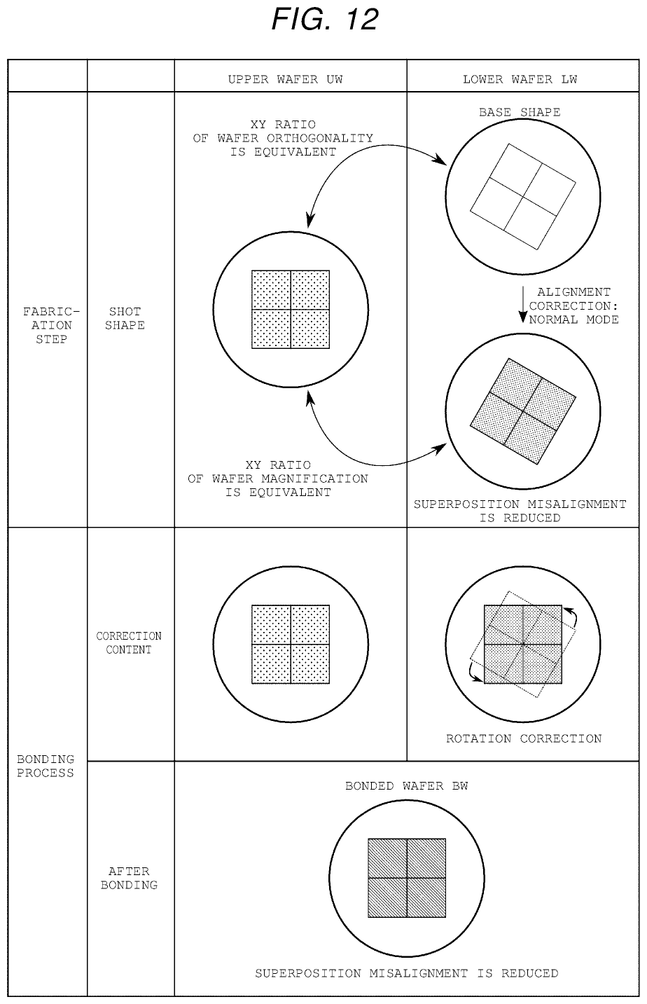

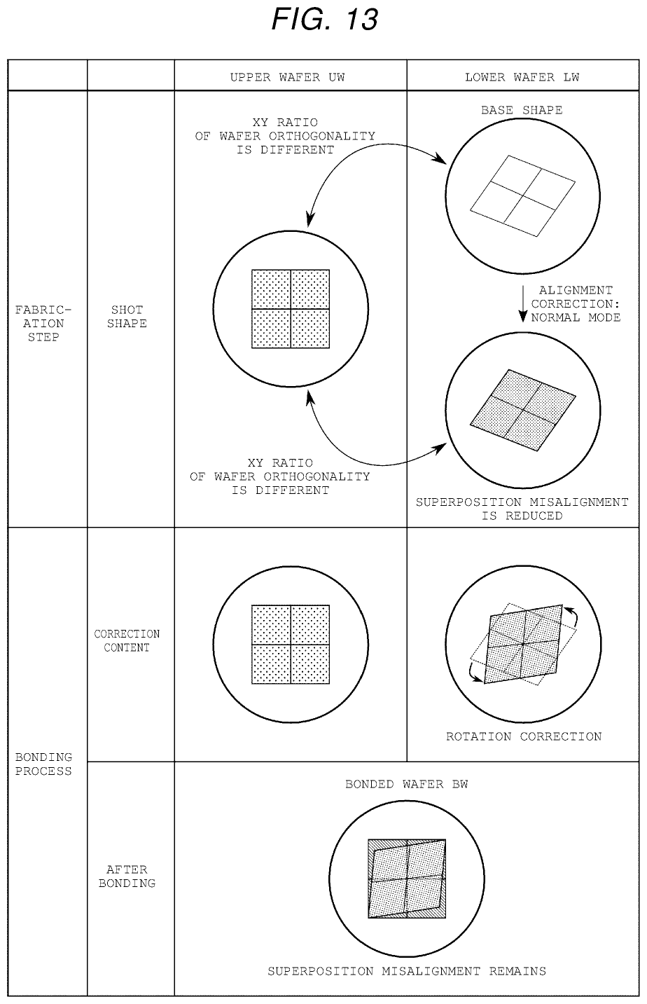

FIG. 12 is a schematic diagram showing an example of a change in the superposition misalignment of the wafer orthogonality when the alignment correction in the normal mode is used in the step of manufacturing the semiconductor device according to the first embodiment. As shown in FIG. 12, the XY ratio of the wafer orthogonality of the lower wafer LW in this example is equivalent to the XY ratio of the wafer orthogonality of the base shape of the upper wafer UW. In this example, since the alignment correction setting is the normal mode, the shot shape to which the wafer component correction is applied by the exposure process is corrected to be substantially the same as the base shape. Therefore, in the exposure process of the lower wafer LW, the occurrence of superposition misalignment of the wafer orthogonality is reduced. The XY ratio of the wafer orthogonality of the lower wafer LW after the exposure process is equivalent to the XY ratio of the wafer orthogonality of the upper wafer UW. After that, the bonding device applies the wafer orthogonality correction (that is, rotation correction) common to XY to the lower wafer LW to execute the bonding process. In this example, since the XY ratio of the wafer orthogonality of the upper wafer UW is equivalent to the XY ratio of the wafer orthogonality of the lower wafer LW at the time of the bonding process, the superposition misalignment of the wafer orthogonality between the upper wafer UW and the lower wafer LW in the bonded wafer BW is reduced.

FIG. 13 is a schematic diagram showing an example of a change in the superposition misalignment of the wafer orthogonality when the alignment correction in the normal mode is used in the step of manufacturing the semiconductor device according to the first embodiment. As shown in FIG. 13, the XY ratio of the wafer orthogonality of the lower wafer LW in this example is different from the XY ratio of the wafer orthogonality of the base shape of the upper wafer UW. In this example, since the alignment correction setting is the normal mode, the shot shape to which the wafer component correction is applied by the exposure process is corrected to be substantially the same as the base shape. Therefore, in the exposure process of the lower wafer LW, the occurrence of superposition misalignment of the wafer orthogonality is reduced. The XY ratio of the wafer orthogonality of the lower wafer LW after the exposure process is different from the XY ratio of the wafer orthogonality of the upper wafer UW. After that, the bonding device applies the wafer orthogonality correction (that is, rotation correction) common to XY to the lower wafer LW to execute the bonding process. In this example, the XY ratio of the wafer orthogonality of the upper wafer UW is different from the XY ratio of the wafer orthogonality of the lower wafer LW at the time of the bonding process, and the bonding device cannot correct the XY difference of the wafer orthogonality, so that the superposition misalignment between the wafer orthogonality with the upper wafer UW and the lower wafer LW in the bonded wafer BW remains.

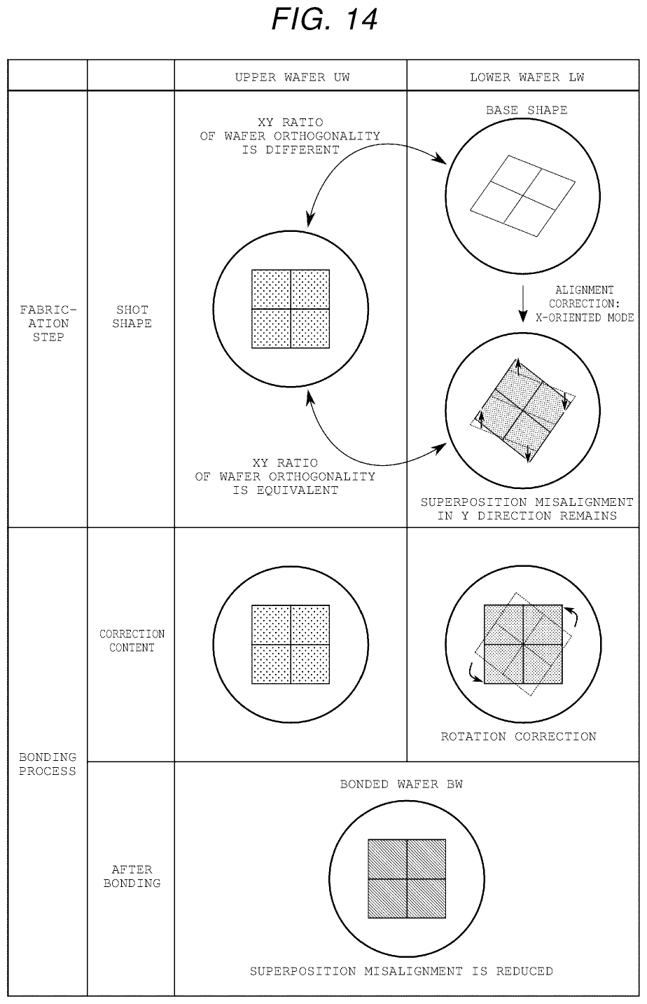

FIG. 14 is a schematic diagram showing an example of a change in the superposition misalignment of the wafer orthogonality when the alignment correction in the X-oriented mode is used in the step of manufacturing the semiconductor device according to the first embodiment. As shown in FIG. 14, the XY ratio of the wafer orthogonality of the lower wafer LW in this example is different from the XY ratio of the wafer orthogonality of the upper wafer UW. In this example, since the alignment correction setting is the X-oriented mode, the wafer orthogonality applied to the correction of the wafer component in the exposure process is equivalent to the XY ratio of the wafer orthogonality of the upper wafer UW, and the superposition misalignment with the base shape is reduced only in the X direction. Therefore, in the exposure process of the lower wafer LW, the occurrence of the superposition misalignment of the wafer orthogonality in the X direction is reduced, and the superposition misalignment of the wafer orthogonality in the Y direction remains. After that, the bonding device applies the wafer orthogonality correction (that is, rotation correction) common to XY to the lower wafer LW to execute the bonding process. In this example, since the XY ratio of the wafer orthogonality of the upper wafer UW is equivalent to the XY ratio of the wafer orthogonality of the lower wafer LW at the time of the bonding process, the superposition misalignment of the wafer orthogonality between the upper wafer UW and the lower wafer LW in the bonded wafer BW is reduced.

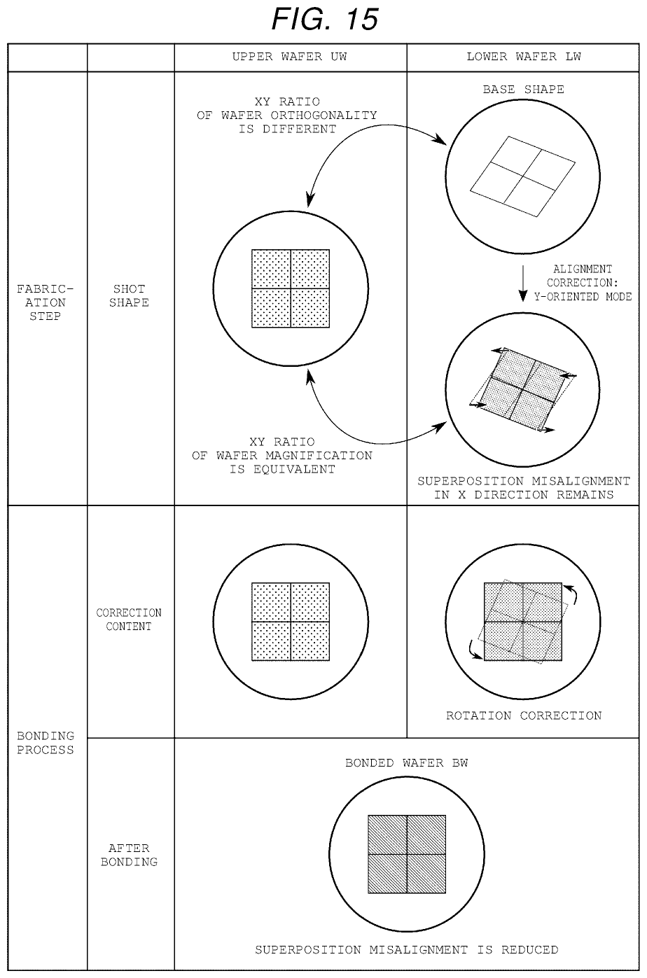

FIG. 15 is a schematic diagram showing an example of a change in the superposition misalignment of the wafer orthogonality when the alignment correction of the Y-oriented mode is used in the step of manufacturing the semiconductor device according to the first embodiment. As shown in FIG. 15, the XY ratio of the wafer orthogonality of the lower wafer LW in this example is different from the XY ratio of the wafer orthogonality of the upper wafer UW. In this example, since the alignment correction setting is the Y-oriented mode, the wafer orthogonality applied to the correction of the wafer component in the exposure process is equivalent to the XY ratio of the wafer orthogonality of the upper wafer UW, and the superposition misalignment with the base shape is reduced only in the Y direction. Therefore, in the exposure process of the lower wafer LW, the occurrence of the superposition misalignment of the wafer orthogonality in the Y direction is reduced, and the superposition misalignment of the wafer orthogonality in the X direction remains. After that, the bonding device applies the wafer orthogonality correction (that is, rotation correction) common to XY to the lower wafer LW to execute the bonding process. In this example, since the XY ratio of the wafer orthogonality of the upper wafer UW is equivalent to the XY ratio of the wafer orthogonality of the lower wafer LW at the time of the bonding process, the superposition misalignment of the wafer orthogonality between the upper wafer UW and the lower wafer LW in the bonded wafer BW is reduced.

### [1-3] Effect of First Embodiment

According to the exposure device 1 according to the first embodiment described above, the yield of the semiconductor device can be improved. The details of the effect of the exposure device 1 according to the first embodiment will be described below.

A known bonding device only allows to use the same value for the component in the X direction and the component in the Y direction when correcting the wafer magnification and the superposition misalignment of the rotation component between the upper wafer UW and the lower wafer LW. In the bonded wafer BW formed by the bonding device, when the XY difference in the wafer magnification between the upper wafer UW and the lower wafer LW varies between the wafers, as described with reference to FIG. 9, there is a possibility that the superposition misalignment between the upper wafer UW and the lower wafer LW remains. Similarly, when the XY difference between the wafer orthogonality of the upper wafer UW and the wafer orthogonality of the lower wafer LW varies between the wafers, as described with reference to FIG. 13, there is a possibility that the superposition misalignment between the upper wafer UW and the lower wafer LW remains.

As a method for improving the superposition misalignment in the bonding process, it is conceivable to adjust the XY difference between the wafer magnification and the wafer orthogonality in the pattern of the bonding surface of the lower wafer LW according to the upper wafer UW. As a result, the superposition misalignment of the lower wafer LW and the upper wafer UW in the bonding process may be reduced. However, when the pattern of the bonding surface of the lower wafer LW is adjusted according to the upper wafer UW, the superposition misalignment of the pattern of the bonding surface with the pattern of the base thereof may remain as described with reference to FIGS. 10, 11, 13 and 14.

On the other hand, the range, in which the superposition misalignment of the pattern of the bonding surface with the pattern of the base may be allowed, may be narrow in one of the X direction and the Y direction and wide in the other direction. That is, priority is given to the correction of the superposition misalignment between the upper wafer UW and the lower wafer LW, and, even when the superposition misalignment between the pattern of the bonding surface in the lower wafer LW and the pattern of the base is deteriorated, there is a possibility that the effect on the yield is small for the superposition misalignment of one of the X direction and the Y direction.

Therefore, the exposure device 1 according to the first embodiment has a function of determining the correction value of the wafer magnification in the other direction based on one of the correction values of the wafer magnifications of the correction values of the wafer magnifications in the X direction and the Y direction, which are obtained by the measurement of the alignment mark AM in the exposure process.

Specifically, when the X-oriented mode is used, the exposure device 1 may determine the correction value of the wafer magnification in the X direction of the lower wafer LW according to the base, and the correction value of the wafer magnification in the Y direction based on the wafer magnification correction ratio. When the X-oriented mode is used, the exposure device 1 may determine the correction value of the wafer orthogonality in the X direction of the lower wafer LW according to the base, and the correction value of the wafer orthogonality in the Y direction based on the wafer rotation correction ratio. Further, when the Y-oriented mode is used, the exposure device 1 may determine the correction value of the wafer magnification in the Y direction of the lower wafer LW to the base, and sets the correction value of the wafer magnification in the X direction based on the wafer magnification correction ratio. When the Y-oriented mode is used, the exposure device 1 may determine the correction value of the wafer orthogonality in the X direction of the lower wafer LW according to the base, and the correction value of the wafer orthogonality in the Y direction based on the wafer rotation correction ratio.

Then, in the exposure device 1 according to the first embodiment, the alignment correction setting may be properly used according to the tendency of the range in which the superposition misalignment in each of the X direction and the Y direction in each processing step may be allowed. Specifically, when the range in which the superposition misalignment may be allowed is wide only on the Y direction side, it is preferable that the X-oriented mode is used as the setting of the alignment correction. When the range in which the superposition misalignment may be allowed is wide only on the X direction side, it is preferable that the Y-oriented mode is used as the setting of the alignment correction. When the range in which the superposition misalignment may be allowed is difficult to achieve in both the X direction and the Y direction, it is preferable to use the normal mode in which the superposition misalignment component in the X direction and the Y direction is aligned with the base as the setting of the alignment correction.

As described above, the exposure device 1 according to the first embodiment uses the X-oriented mode or the Y-oriented mode, so that the superposition misalignment increases on a side where the range in which the superposition misalignment may be allowed is wide, but the superposition misalignment in the direction in which the effect to the yield is large may be reduced. In other words, the exposure device 1 according to the first embodiment appropriately allows the superposition misalignment in the step and the direction where the range in which the superposition misalignment may be allowed is wide, so that the superposition misalignment may be reduced in a step and a direction where the range in which the superposition misalignment may be allowed is narrow, and the yield of the semiconductor device can be improved.

### [2] Second Embodiment

A second embodiment relates to a semiconductor manufacturing system that changes the correction value of the wafer magnification of the lower wafer LW in the bonding process based on the exposure result of the lower wafer LW and the upper wafer UW. The details of a semiconductor manufacturing system PS according to the second embodiment will be described below.

### [2-1] Configuration

### [2-1-1] Configuration of Semiconductor Manufacturing System PS

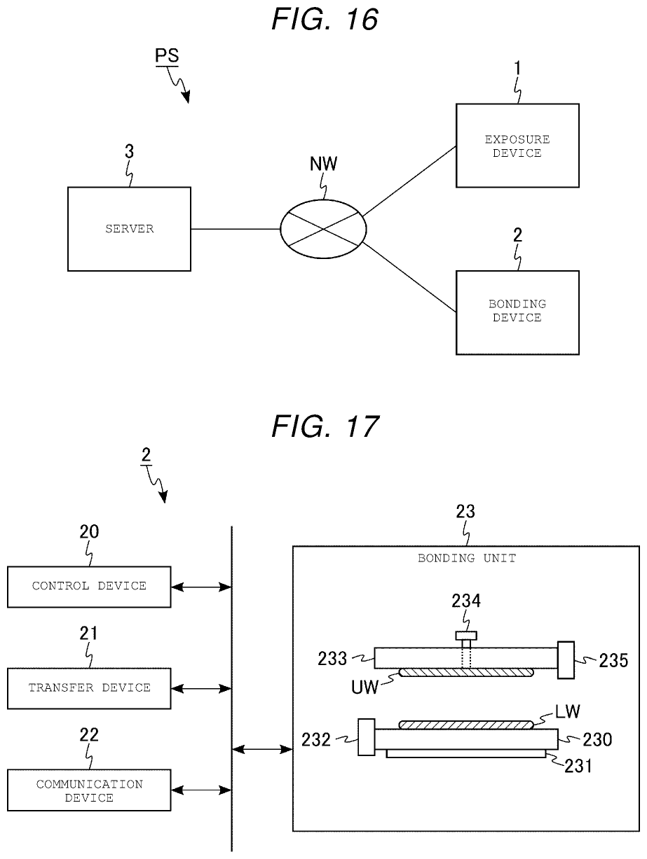

FIG. 16 is a block diagram showing an example of the configuration of the semiconductor manufacturing system PS according to the second embodiment. As shown in FIG. 16, the semiconductor manufacturing system PS includes, for example, an exposure device 1, a bonding device 2, and a server 3. The exposure device 1, the bonding device 2, and the server 3 are configured to be communicable via a network NW. As the network NW, wired communication may be used, or wireless communication may be used.

### [2-1-2] Configuration of Bonding Device 2

FIG. 17 is a block diagram showing an example of the configuration of the bonding device 2 according to the second embodiment. As shown in FIG. 17, the bonding device 2 includes, for example, a control device 20, a transfer device 21, a communication device 22, and a bonding unit 23.

The control device 20 is a computer or the like that controls the overall operation of the bonding device 2. The control device 20 controls each of the transfer device 21, the communication device, and the bonding unit 23. The control device 20 includes a CPU, a ROM, a RAM, and the like, similar to the control device 10 of exposure device 1.

The transfer device 21 is a device including a transfer arm capable of transferring the wafer, a transition for temporarily placing a plurality of wafers, and the like. For example, the transfer device 21 transfers the upper wafer UW and the lower wafer LW received from a pre-processing device for the bonding process to the bonding unit 23. Further, the transfer device 21 transfers the bonded wafer BW received from the bonding unit 23 to the outside of the bonding device 2 after the bonding process. The transfer device 21 may include a mechanism that reverses the wafer upside down.

The communication device 22 is a communication interface that may be connected to the network NW. The bonding device 2 may operate based on the control of a terminal on the network NW, may store an operation log in the server 3 on the network NW, or may calculate the correction value of the superposition misalignment based on information stored in the server 3.

The bonding unit 23 is a set of configurations used in the bonding process. The bonding unit 23 includes, for example, a lower stage 230, a stress device 231, a camera 232, an upper stage 233, a pressing pin 234, and a camera 235. The lower stage 230 has a function of holding the lower wafer LW. The lower stage 230 includes, for example, a wafer chuck that holds the wafer by vacuum suction. The stress device 231 has a function of applying stress to the lower stage 230 to deform the lower wafer LW via the lower stage 230. The expansion amount (scaling) of the lower wafer LW held by the lower stage 230 changes according to the deformation amount of the lower stage 230 by the stress device 231. The camera 232 is an imaging mechanism disposed on a side of the lower stage 230 and used for measuring the alignment mark AM of the upper wafer UW. The upper stage 233 has a function of holding the upper wafer UW. The upper stage 233 includes, for example, a wafer chuck that holds the wafer by vacuum suction. The pressing pin 234 is a pin that is driven in the vertical direction based on the control of the control device 20 and may push the upper surface of the central portion of the upper wafer UW held by the upper stage 233. The camera 235 is an imaging mechanism disposed on a side of the upper stage 233 and used for measuring the alignment mark AM of the lower wafer LW. The bonding device 2 may have a vacuum pump to provide vacuum suction at the lower stage 230 and the upper stage 233.

The lower stage 230 and the upper stage 233 are configured so that the lower wafer LW (held by the lower stage 230) and the upper wafer UW (held by the upper stage 233) may face each other. That is, the upper stage 233 may be disposed above the lower stage 230. In other words, the lower stage 230 and the upper stage 233 may face each other. In the bonding process, the upward facing surface of the upper wafer UW is the back surface and it is the back surface that is held by the upper stage 233 of the bonding device 2. The downward facing surface of the upper wafer UW is the primary surface of the upper wafer UW and corresponds to the bonding surface. The upward facing surface of the lower wafer LW is the primary surface of the lower wafer LW and corresponds to the bonding surface. The downward surface of the lower wafer LW is the back surface of the lower wafer LW and is held by the lower stage 230 of the bonding device 2. The bonding device 2 may adjust the shift component and the rotation component of the superposition misalignment by adjusting the relative positions of the lower stage 230 and the upper stage 233. Further, the bonding device 2 may adjust the wafer magnification common to XY of the lower wafer LW held by the deformed lower stage 230 by deforming the lower stage 230 by the stress device 231.

The above-described “pre-processing device for the bonding process” is a device having a function of modifying and hydrophilizing the bonding surfaces of the upper wafer UW and the lower wafer LW so that the respective bonding surfaces may be bonded. In the present example, the pre-processing device first performs plasma processing on the respective surfaces of the upper wafer UW and the lower wafer LW. In the plasma processing, oxygen ions or nitrogen ions are generated from oxygen gas or nitrogen gas under a low pressure atmosphere, and the bonding surfaces of the respective wafers are exposed to the generated oxygen ions or nitrogen ions. After that, the pre-processing device supplies high purity water to the respective surfaces of the upper wafer UW and the lower wafer LW. By such treatment, hydroxyl groups are formed adhering to the respective surfaces of the upper wafer UW and the lower wafer LW, and the surfaces can be said to be hydrophilized. In the bonding process, plasma treated and hydrophilized wafers are used. The bonding device 2 may be combined with a pre-processing device or the like to form a bonding system.

### [2-1-3] Configuration of Server 3

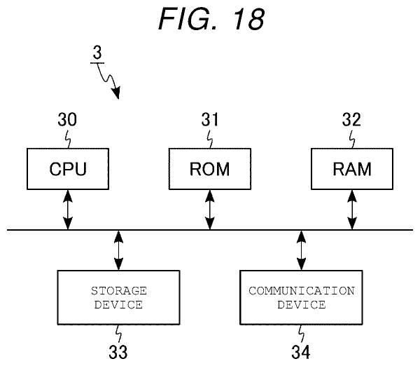

FIG. 18 is a block diagram showing an example of the configuration of the server 3 according to the second embodiment. As shown in FIG. 18, the server 3 includes, for example, a CPU 30, a ROM 31, a RAM 32, a storage device 33, and a communication device 34. The CPU 30 is a processor that executes various programs related to the control of the server 3. The ROM 31 is a non-volatile storage device that stores a control program for the server 3. The RAM 32 is a volatile storage device used as a work area for the CPU 30. The storage device 33 is a non-volatile storage medium capable of storing information received from the exposure device 1, the bonding device 2, and the like. The communication device 34 is a communication interface that may be connected to the network NW.

### [2-2] Method for Manufacturing Semiconductor Device

Hereinafter, an example of a specific process using the bonding device 2 will be described as a method for manufacturing a semiconductor device according to the second embodiment. That is, the semiconductor device is manufactured by using a bonding method (bonding process) of the second embodiment which will be described below. In the following description, the alignment of the shift component is referred to as “shift alignment”, and the alignment of the rotation component is referred to as “rotation alignment”. That is, the alignment correction (or simply “alignment”) includes the shift alignment and the rotation alignment. In the present specification, each of the “shift alignment” and the “rotation alignment” includes measurement of at least one associated alignment mark AM and calculation of an alignment correction value based on the measurement result of the alignment mark AM.

### [2-2-1] Outline of Bonding Process

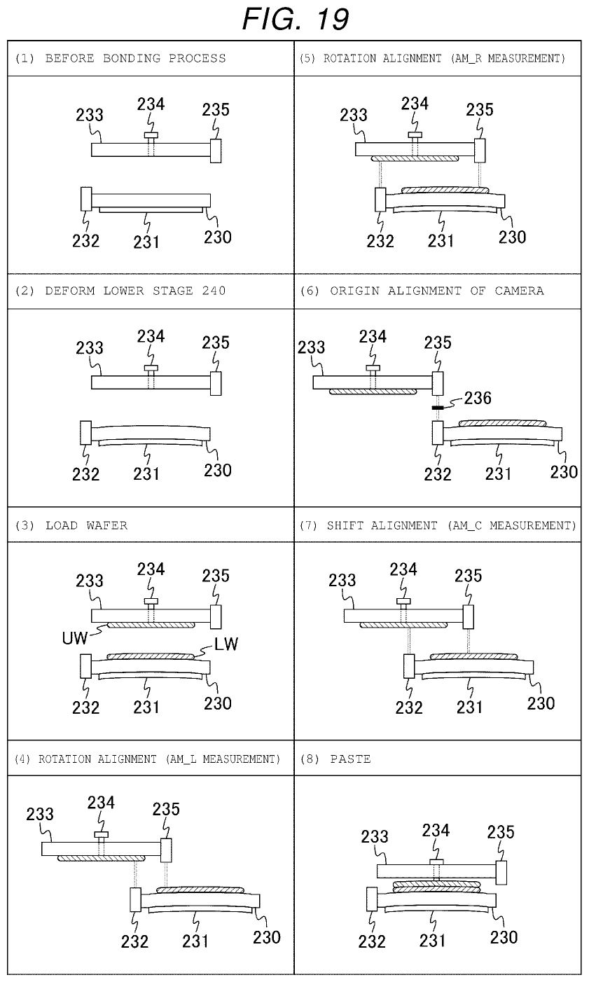

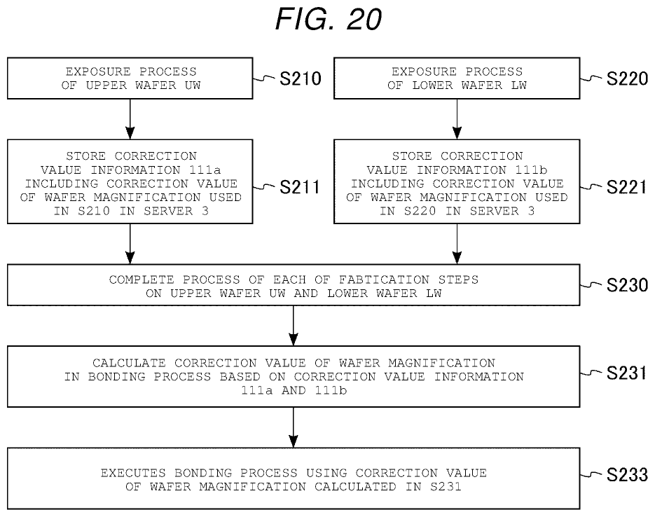

FIG. 19 is a schematic diagram showing an outline of the bonding process of the bonding device 2 according to the second embodiment. In the bonding process, each of stages (1) to (8) of FIG. 19 shows the state of the bonding unit 23 during the bonding process.

Stage (1) of FIG. 19 shows the state of the bonding unit 23 at the start of the bonding process.

When the bonding process starts, the control device 20 controls the stress device 241 based on the correction value of the wafer magnification common in the X direction and the Y direction, and deforms the lower stage 240 as shown in stage (2) of FIG. 19.

Next, the control device 20 causes the transfer device 21 to transfer the lower wafer LW to the lower stage 230 and to transfer the upper wafer UW to the upper stage 233. Then, as shown in stage (3) of FIG. 19, the control device 20 causes the lower stage 230 to hold the lower wafer LW and the upper stage 233 to hold the upper wafer UW. The respective surfaces of the upper wafer UW and the lower wafer LW transferred to the bonding device 2 are plasma treated and hydrophilized by the pre-processing device before the bonding process.

Next, the control device 20 executes the rotation alignment. Specifically, first, as shown in stage (4) of FIG. 19, the control device 20 controls the positions of the lower stage 230 and the upper stage 233 to align the optical axis of the camera 232 of the lower stage 230 with the position of the alignment mark AM_L of the upper wafer UW and to align the optical axis of the camera 235 of the upper stage 233 with the position of the alignment mark AM_L of the lower wafer LW. Then, the control device 20 measures the alignment mark AM_L of the upper wafer UW using the camera 232, and measures the alignment mark AM_L of the lower wafer LW using the camera 235.

Next, as shown in stage (5) of FIG. 19, the control device 20 controls the positions of the lower stage 230 and the upper stage 233 to align the optical axis of the camera 232 of the lower stage 230 with the position of the alignment mark AM_R of the upper wafer UW and to align the optical axis of the camera 235 of the upper stage 233 with the position of the alignment mark AM_R of the lower wafer LW. Then, the control device 20 measures the alignment mark AM_R of the upper wafer UW using the camera 232, and measures the alignment mark AM_R of the lower wafer LW using the camera 235. Then, the control device 20 calculates the amount of correction of the superposition misalignment of the rotation component based on the measurement results of the alignment marks AM_L and AM_R by the cameras 232 and 235 acquired by the processes in stages (4) and (5) of FIG. 19.

Next, the control device 20 executes the origin alignment of the camera. Specifically, as shown in stage (6) of FIG. 19, the control device 20 controls the positions of the lower stage 230 and the upper stage 233 to insert a common target 236 between the optical axis of the camera 232 of the lower stage 230 and the optical axis of the camera 235 of the upper stage 233. Then, the control device 20 aligns each of the origins of the cameras 232 and 235 based on the measurement result of the common target 236 by each of the cameras 232 and 235.

Next, the control device 20 executes the shift alignment. Specifically, as shown in stage (7) of FIG. 19, the control device 20 first controls the positions of the lower stage 230 and the upper stage 233 to align the optical axis of the camera 232 of the lower stage 230 with the position of the alignment mark AM_C of the upper wafer UW and to align the optical axis of the camera 235 of the upper stage 233 with the position of the alignment mark AM_C of the lower wafer LW. Then, the control device 20 measures the alignment mark AM_C of the upper wafer UW using the camera 232, and measures the alignment mark AM_C of the lower wafer LW using the camera 235. Then, the control device 20 calculates the correction value of the superposition misalignment of the shift component based on the measurement result of the alignment mark AM_C of each of the lower wafer LW and the upper wafer UW.

Next, the control device 20 executes a bonding process as shown in stage (8) of FIG. 19. Specifically, the control device 20 performs alignment in the horizontal direction based on the correction value calculated by each of the rotation alignment and the shift alignment and the calibration result of the origin of the camera, and adjusts the relative positions of the lower stage 230 and the upper stage 233. Then, the control device 20 brings the position of the upper stage 233 closer to the lower stage 230 and adjusts the interval between the upper wafer UW and the lower wafer LW. Then, the control device 20 pushes down the central portion of the upper wafer UW by lowering the pressing pin 244 to cause the surface of the upper wafer UW to come into contact with the surface of the lower wafer LW.

After that, the control device 20 releases the holding of the upper wafer UW by the upper stage 243 in order from the inside to the outside. Then, the upper wafer UW descends onto the lower wafer LW, and the surface of the upper wafer UW and the surface of the lower wafer LW are bonded to each other. Specifically, a van der Waals force (intramolecular force) is generated between the bonding surfaces at the points of contact between the upper wafer UW and the lower wafer LW. Further, since the bonding surfaces of the upper wafer UW and the lower wafer LW are hydrophilized, the hydrophilic groups at the contact portions of the upper wafer UW and the lower wafer LW may also be hydrogen-bonded (intermolecular force), and the contact portions of the upper wafer UW and the lower wafer LW may be bonded more firmly than otherwise would be the case.

### [2-2-2] Method for Correcting Wafer Magnification

FIG. 20 is a flowchart showing an example of a step related to the correction of the wafer magnification in the bonding process of the bonding device 2 according to the second embodiment.

First, the process of the fabrication steps of each of the upper wafer UW and the lower wafer LW is executed. Specifically, an exposure process of the upper wafer UW is executed (S210). Correction value information 111a including the correction value of the wafer magnification used in the exposure process in step S210 is stored in the server 3 (S211). Similarly, an exposure process of the lower wafer LW is executed (S220). Correction value information 111b including the correction value of the wafer magnification used in the exposure process in step S220 is stored in the server 3 (S221).

When fabrication of the upper wafer UW and the lower wafer LW is completed (S230), the server 3 calculates the correction value of the wafer magnification to be used in the bonding process based on the pieces of correction value information 111a and 111b stored in steps S211 and S221, respectively (S231). Specifically, in step S231, the difference is calculated between the wafer magnification processing value (alignment correction value+overlay correction value) in the upper wafer UW and the wafer magnification processing value (alignment correction value+overlay correction value) in the lower wafer LW. Then, the server 3 feeds forward the calculation result in step S231 to the bonding device 2. In the present specification, the “alignment correction value” is a correction value for accounting for the superposition misalignment calculated based on the measurement result of the alignment mark AM. The “overlay correction value” is a correction value calculated based on the result of exposure OL measurement in, for example, advanced process control executed at the time of large-scale lot processing.

After that, the bonding device 2 executes the bonding process using the correction value of the wafer magnification calculated in step S231 (S233). That is, the bonding device 2 determines the correction value of the wafer magnification in the bonding process based on the alignment results of the respective exposure processes of the upper wafer UW and the lower wafer LW in the previous step. In other words, in the bonding process, the bonding device 2 controls the stress device 231 based on the difference in the alignment results of the respective exposure processes of the upper wafer UW and the lower wafer LW in the previous fabrication steps to deform the lower stage 230 ((2) of FIG. 19). Other operations in the bonding process are the same as the operations described with reference to FIG. 19.

In the above description, the case where the correction value of the wafer magnification in the bonding process is determined by using the server 3 has been illustrated, but the present disclosure is not limited thereto. The exposure device 1 or the bonding device 2 may calculate the correction value of the wafer magnification in the bonding process. In this case, information related to the correction value of the wafer magnification is exchanged between the exposure device 1 and the bonding device 2.

### [2-3] Effect of Second Embodiment

As described with reference to FIGS. 3A to 3C, the bonding device 2 may have fewer measurement points for the alignment mark AM than the exposure device 1. Then, the bonding device 2 may not have a unit that measures the wafer magnification (that is, the size of the wafer) in alignment measurement.

Therefore, in the semiconductor manufacturing system PS according to the second embodiment, the exposure device 1 feeds forward wafer size information (correction value information 111) acquired by the alignment measurement to the bonding device 2. Then, the bonding device 2 uses the correction value of the wafer magnification based on the feed-forwarded correction value information 111 for the bonding process. As a result, the bonding device 2 according to the second embodiment can reduce the occurrence of the superposition misalignment of the wafer magnification in the bonding process, and can improve the yield of the semiconductor device.

### [2-4] Modified Example of Second Embodiment

The change in the size of the wafer held on the stage by vacuum suction or the like (that is, the change in the magnification of the wafer) tends to change depending on the film (film stress) formed on the wafer surface. That is, the amount of warpage of the wafer has a correlation with the wafer magnification. Therefore, in the modified example of the second embodiment, the warpage of each of the upper wafer UW and the lower wafer LW is measured in an earlier step, and the correction value of the wafer magnification in the bonding process is determined based on the measured amount of warpage.

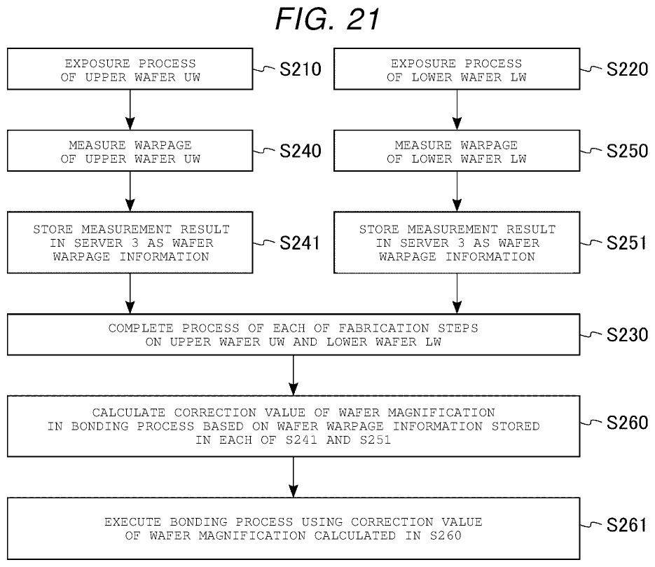

FIG. 21 is a flowchart showing an example of a step related to the correction of the wafer magnification in the bonding process of the bonding device 2 according to the modified example of the second embodiment.

First, the fabrication steps for each of the upper wafer UW and the lower wafer LW are executed. Specifically, in this example, an exposure process on the upper wafer UW is executed (S210). After that, the warpage of the upper wafer UW is measured (S240), and the measurement result in step S240 is stored in the server 3 as the wafer warpage information (S241). Similarly, an exposure process on the lower wafer LW is executed (S220). After that, the warpage of the lower wafer LW is measured (S250), and the measurement result in step S250 is stored in the server 3 as the wafer warpage information (S251). It is preferable that the processes in step S240 and S250 are executed is at a time at which film stress on the surfaces of the upper wafer UW and the lower wafer LW (the amount of warpage of the wafers) matches the film stress level just before the bonding process is executed.

Then, once the fabrication processes of each of the upper wafer UW and the lower wafer LW is completed (S230), the server 3 calculates the correction value of the wafer magnification in the bonding process based on the wafer warpage information stored in each of the steps S241 and S251 (S260). In step S260, the server 3 uses a relational expression between the warpage of the wafer and the wafer magnification for calculating the correction value of the wafer magnification. The relational expression may be calculated based on the measurement results of the warpage and wafer magnification of a plurality of wafers, or may be calculated based on simulation results. Then, the server 3 feeds forward the calculation result in step S260 to the bonding device 2.

After that, the bonding device 2 executes the bonding process using the correction value of the wafer magnification as calculated in step S260 (S261). That is, the bonding device 2 sets the correction value of the wafer magnification used in the bonding process based on the amount of warpage of each of the upper wafer UW and the lower wafer LW in measured in a previous step. More specifically, in the bonding process, the bonding device 2 controls the stress device 231 based on the difference in the measured amount of warpage of each of the upper wafer UW and the lower wafer LW to deform the lower stage 230 ((2) in FIG. 19). Other operations in the bonding process are the same as the operations described with reference to FIG. 19.

Similar to the second embodiment, the method for manufacturing a semiconductor device according to the modified example of the second embodiment described above can reduce the occurrence of the superposition misalignment in the bonding process and can improve the yield of the semiconductor device.

### [3] Third Embodiment

A third embodiment relates to a semiconductor manufacturing system PS that corrects misalignment of the shift component in the bonding process according to the wafer magnification of the lower wafer LW and the upper wafer UW. The details of the semiconductor manufacturing system PS according to the third embodiment will be described below.

### [3-1] Method for Manufacturing Semiconductor Device

Hereinafter, an example of a specific process using the semiconductor manufacturing system PS will be described as a method for manufacturing a semiconductor device according to the third embodiment. That is, a semiconductor device is manufactured by using a bonding method (bonding process) of the third embodiment.

### [3-1-1] Method for Creating Correction Formula

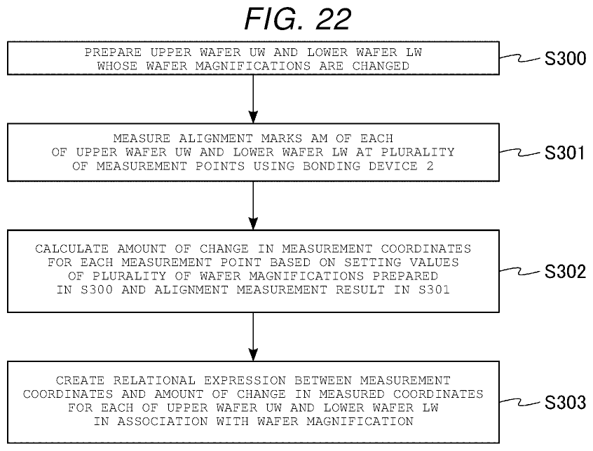

FIG. 22 is a flowchart showing an example of a method for creating a superposition misalignment correction formula used in the bonding device 2 according to the third embodiment.

First, an upper wafer UW and a lower wafer LW whose wafer magnifications are changed are prepared in a predetermined step (S300). A wafer magnification condition is two or more conditions, and it is preferable that the wafer magnification is prepared in as many conditions as possible. The predetermined step corresponds to, for example, an exposure process of the wiring layer near the respective surfaces of the upper wafer UW and the lower wafer LW.

Next, the alignment marks AM of each of the upper wafer UW and the lower wafer LW are measured at a plurality of measurement points using the bonding device 2 (S301). The bonding device 2 utilizes the correction of the wafer magnification using the stress device 231 when measuring the alignment marks AM. That is, at the time of measuring the alignment marks AM, the lower wafer LW is in a state where the wafer magnification is corrected. Then, the alignment measurement result is stored in, for example, the server 3.

Next, the server 3 calculates the amount of change in the measured coordinates for each measurement point based on the setting values of the plurality of wafer magnifications prepared in step S300 and the alignment measurement result in step S301 (S302).

Next, the server 3 creates a relational expression between the measured coordinates and the amount of change in the measured coordinates for each of the upper wafer UW and the lower wafer LW in association with the wafer magnification (S303). This relational expression (correction formula) is calculated, for example, by performing a function approximation on the calculation result in step S302 in the orthogonal coordinate system. The correction formula for the lower wafer LW is associated with the correction value of the magnification component used in the exposure process of the lower wafer LW, and shows the relationship between the measured coordinates of the alignment mark AM of the lower wafer LW and the measurement errors of the measured coordinates and the central position of the lower wafer LW. The correction formula of the upper wafer UW is associated with the correction value of the magnification component used in the exposure process of the upper wafer UW, and shows the relationship between the measured coordinates of the alignment mark AM of the upper wafer UW and the measurement errors of the measured coordinates and the central position of the upper wafer UW. The relational expression between the measured coordinates and the amount of change in the measured coordinates at each wafer magnification of the upper wafer UW and the lower wafer LW may be stored in the server 3 or transferred to the bonding device 2.

### [3-1-2] Bonding Process

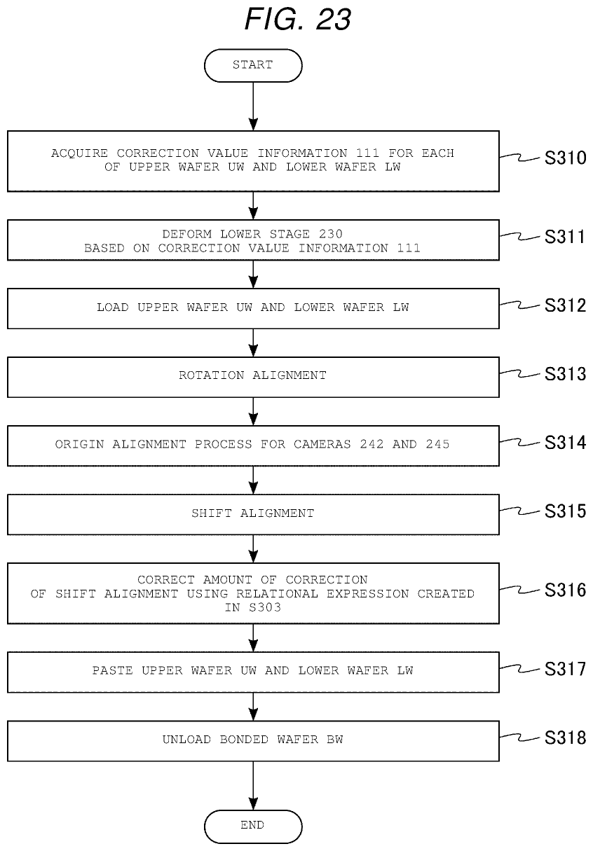

FIG. 23 is a flowchart showing an example of the bonding process of the bonding device 2 according to the third embodiment.

The bonding device 2 starts the bonding process when the pre-processing device for the bonding process notifies that the pre-processing of the wafer is completed (start).

First, the bonding device 2 acquires correction value information 111 for each of the upper wafer UW and the lower wafer LW (S310). The bonding device 2 may acquire the correction value information 111 from the server 3 or the exposure device 1.

Next, the bonding device 2 deforms the lower stage 230 based on the correction value information 111 (S311). The process in step S317 is the same as the process in (2) of FIG. 19 described in the second embodiment.

Next, the bonding device 2 loads the upper wafer UW and the lower wafer LW (S312). The process in step S312 is the same as the process in (3) of FIG. 19 described in the second embodiment.

Next, the bonding device 2 performs the rotation alignment (S313). The process in step S313 is the same as the process in (4) and (5) of FIG. 19 described in the second embodiment.

Next, the bonding device 2 executes an origin alignment process for the cameras 242 and 245 (S314). The process in step S314 is the same as the process in (6) of FIG. 19 described in the second embodiment.

Next, the bonding device 2 executes the shift alignment (S315). The process in step S315 is the same as the process in (7) of FIG. 19 described in the second embodiment.

Next, the bonding device 2 corrects the amount of correction of the shift alignment by using the relational expression created in step S303 (S316). Specifically, the control device 20 acquires each of the correction values of the wafer magnification of the upper wafer UW and the wafer magnification of the lower wafer LW from the correction value information 111. Then, the control device 20 substitutes the measured coordinates of the alignment mark AM_C of the upper wafer UW into the relational expression corresponding to the wafer magnification of the upper wafer UW created in step S303, thereby calculating the amount of deception of the measurement result of the shift alignment in the upper wafer UW. Similarly, the control device 20 substitutes the measured coordinates of the alignment mark AM_C of the lower wafer LW into the relational expression corresponding to the wafer magnification of the lower wafer LW created in step S303, thereby calculating the amount of deception of the measurement result of the shift alignment in the lower wafer LW. Then, the control device 20 considers the amount of deception of the measurement result of the shift alignment of each of the upper wafer UW and the lower wafer LW, and shows that the amount of correction of the shift alignment in the bonding process, that is, “the amount of deception of the measurement result of the shift alignment” is the amount of deviation between the coordinates of the center of the wafer obtained from the measurement result of the shift alignment and the actual position of the center of the wafer. “The deception of the measurement result of the shift alignment” may occur depending on the distance between the measured coordinates of the alignment mark AM_C and the position of the center of the wafer and the magnitude of the wafer magnification when the position of the center of the wafer is estimated from the measurement result of the alignment mark AM_C.

In other words, the control device 20 adjusts the relative positions of the first stage and the second stage based on the measurement result of the alignment mark AM_C of the lower wafer LW, the measurement result of the alignment mark AM_C of the upper wafer UW, the correction formula associated with the lower wafer LW, and the correction formula associated with the upper wafer UW. Specifically, the control device 10 adjusts the relative positions of the first stage and the second stage based on the numerical value obtained by adding the measurement error calculated by using the correction formula associated with the lower wafer LW to the measurement result of the alignment mark AM_C of the lower wafer LW, and the numerical value obtained by adding the measurement error calculated by using the correction formula associated with the upper wafer UW to the measurement result of the alignment mark AM_C of the upper wafer UW. The processes in steps S315 and S316 may be integrated.

Next, the bonding device 2 bonds the upper wafer UW and the lower wafer LW (S317). The process in step S317 is the same as the process in (8) of FIG. 19 described in the second embodiment.

Next, the bonding device 2 unloads the bonded wafer BW (S318).

When the bonded wafer BW is unloaded, the bonding device 2 ends the bonding process (end).

When the wafer magnification value acquired from the correction value information 111 and the wafer magnification associated with the relational expression created in step S303 do not coincide with each other in step S316, the control device 20 may use a relational expression created with the closer wafer magnification. Further, the control device 20 may create a relational expression that predicts the relationship between the wafer magnification and the amount of deception of the measurement result of the shift alignment based on a plurality of relational expressions at the time of creating the correction value, and may use the relational expression in step S316.

### [3-1-3] Specific Example

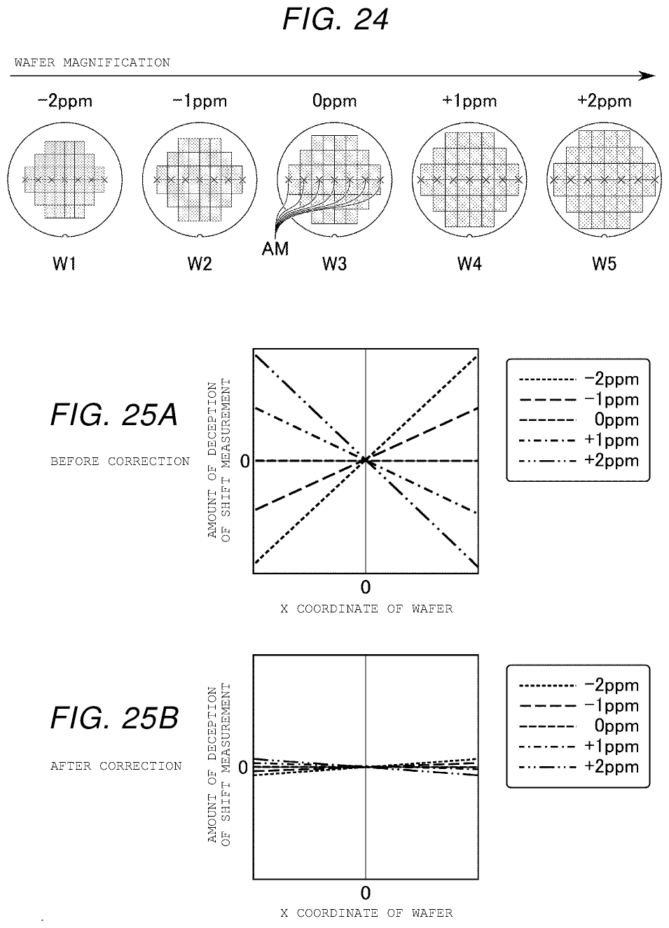

FIG. 24 is a schematic diagram showing an example of a plurality of wafers used for creating the superposition misalignment correction formula used in the bonding device 2 according to the third embodiment. FIG. 24 illustrates wafers W1 to W5 in which the exposure process is performed while changing the wafer magnifications. The wafer magnifications of the respective wafers W1, W2, W3, W4 and W5 are set to −2 ppm, −1 ppm, 0 ppm, +1 ppm and +2 ppm, respectively. As shown in the drawing, when the wafer magnification is changed, the sizes of the plurality of shots in the wafer surface change. Since the patterns of the wafers W1 to W5 are formed using the same mask, the alignment mark AM is disposed at the same coordinates. However, since the wafers W1 to W5 have different wafer magnifications, the actual position of the alignment mark AM on the wafer is misaligned according to the wafer magnification. Specifically, as the wafer magnification becomes smaller, the alignment mark AM is disposed closer to the center side, and as the wafer magnification becomes larger, the alignment mark AM is disposed closer to the outer peripheral side.

FIGS. 25A and 25B are graphs showing examples of a change in the amount of deception of the measurement result of the shift alignment before and after creating the superposition misalignment correction formula in the bonding process of the bonding device 2 according to the third embodiment. FIGS. 25A and 25B show the relationship between the wafer X coordinates and the amount of deception of the shift measurement, which corresponds to the measurement results of the wafers W1 to W5. The server 3 obtains the measurement result as shown in FIG. 25A based on the method for creating the correction formula described in [3-1-1]. The slope of the amount of deception of the shift measurement before correction increases as the wafer magnification increases. Then, in this example, the server 3 calculates a correction formula for the amount of deception of the measurement result of the shift alignment in each of the cases where the wafer magnifications are −2 ppm, −1 ppm, 0 ppm, +1 ppm, and +2 ppm, respectively. As a result, as shown in FIG. 25B, the slope of the amount of deception of the shift measurement after correction goes into a value smaller than that before the correction. That is, the deception of shift measurement may be reduced regardless of the position of the wafer X coordinate.

### [3-2] Effect of Third Embodiment

In the shift alignment, the bonding device 2 calculates the shift amount from the measurement result of the alignment mark AM_C at one point in the wafer surface. However, when the wafer magnification fluctuates, the measurement result of the alignment mark AM_C by the bonding device 2 may be misaligned from the coordinates of the alignment mark AM_C with reference to the exposure device 1 (deception of the measurement). That is, there is a problem that the measurement result of the alignment fluctuates due to the variation in the wafer magnification so that superposition misalignment occurs between the upper wafer UW and the lower wafer LW in the bonding process.

Therefore, in the third embodiment, the exposure device 1 sends the processing result of the exposure device 1 from a previous fabrication step (correction value information 111 including the wafer magnification) to the bonding device 2. Then, the bonding device 2 corrects the amount of deception of the measurement of the shift alignment measurement due to the wafer magnification based on the processing result of the wafer magnification received from the exposure device 1. That is, the bonding device 2 according to the third embodiment predicts and corrects the amount of positional misalignment in the measured coordinates according to the wafer magnification of the upper wafer UW and the lower wafer LW.

As a result, the bonding device 2 according to the third embodiment can alleviate the amount of positional misalignment from a device reference due to the wafer magnification. Therefore, the method for manufacturing a semiconductor device according to the third embodiment can reduce the occurrence of the superposition misalignment in the bonding process and can improve the yield of the semiconductor device.

### [3-3] Modified Example of Third Embodiment

In the third embodiment, the case of correcting the deception of the measurement based on the wafer magnification is illustrated, but the present disclosure is not limited thereto. The bonding device 2 may correct the amount of deception of the wafer measurement based on the wafer warpage information. The amount of warpage of the wafer has a correlation with the wafer magnification as described in the second embodiment. Therefore, the bonding device 2 may estimate the amount of correction of the wafer magnification based on the amount of warpage of the wafer. Therefore, the bonding device 2 may use the relational expression created in step S303 by using the wafer magnification based on the warpage information of each of the upper wafer UW and the lower wafer LW, and may correct the deception of the measurement. In each of the upper wafer UW and the lower wafer LW, a relational expression between the amount of warpage of the wafer and the amount of deception of the measurement may be created. Further, the bonding device 2 may use both the amount of warpage of the wafer and the correction value information 111 including the wafer magnification when selecting the relational expression to be used. In the third embodiment, the occurrence of the relational expression for the upper wafer UW, in which the deception of the measurement is relatively less likely to occur, may be omitted. In this case, both the process of forming the relational expression corresponding to the upper wafer UW and the process of correcting the deception of the measurement are omitted.

### [4] Fourth Embodiment

A fourth embodiment relates to a specific example of a semiconductor device to which the method for manufacturing the semiconductor device described in the first to third embodiments may be applied. Hereinafter, a memory device 4, which is a NAND flash memory, will be described as a specific example of a semiconductor device.

### [4-1] Configuration

### [4-1-1] Configuration of Memory Device 4

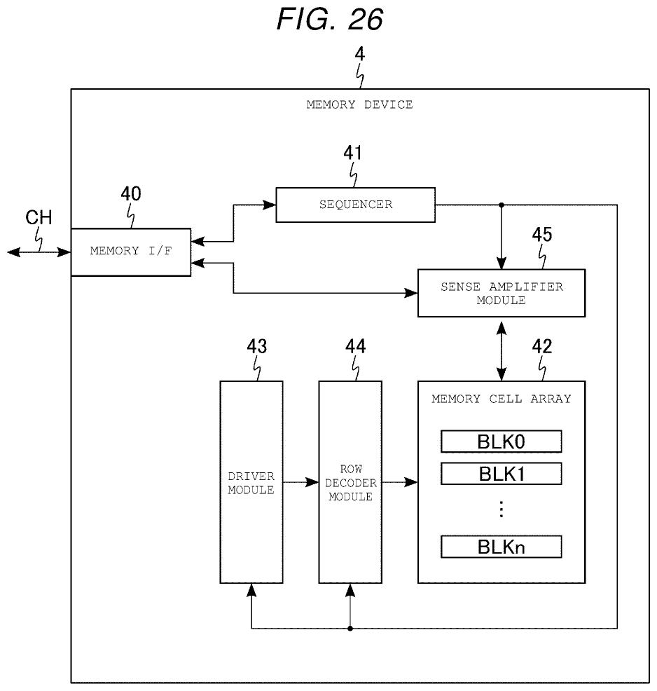

FIG. 26 is a block diagram showing an example of the configuration of the memory device 4 according to the fourth embodiment. As shown in FIG. 26, the memory device 4 includes, for example, a memory interface (memory I/F) 40, a sequencer 41, a memory cell array 42, a driver module 43, a row decoder module 44, and a sense amplifier module 45.

The memory I/F 40 is a hardware interface connected to an external memory controller. The memory I/F 40 performs communication according to the interface standard between the memory device 4 and the memory controller. The memory I/F 40 supports, for example, the NAND interface standard.

The sequencer 41 is a control circuit that controls the overall operation of the memory device 4. The sequencer 41 controls the driver module 43, the row decoder module 44, the sense amplifier module 45, and the like based on the command received via the memory I/F 40 to execute a read operation, a write operation, an erasing operation, and the like.

The memory cell array 42 is a storage circuit including a set of a plurality of memory cells. The memory cell array 42 includes a plurality of blocks BLK0 to BLKn (n is an integer equal to or larger than 1). The block BLK is used, for example, as a data erasing unit. Further, the memory cell array 42 is provided with a plurality of bit lines and a plurality of word lines. Each memory cell is associated with, for example, one bit line and one word line. Each memory cell can be identified based on an address that identifies the word line WL and an address that identifies the bit line BL.

The driver module 43 is a driver circuit that generates a voltage used in the read operation, the write operation, the erasing operation, and the like. The driver module 43 is connected to the row decoder module 44 via a plurality of signal lines. The driver module 43 may change the voltage applied to each of the plurality of signal lines based on a page address received via the memory I/F 40.

The row decoder module 44 is a decoder that decodes a row address received via the memory I/F 40. The row decoder module 44 selects one block BLK based on a result of the decoding. Then, the row decoder module 44 transfers the voltage applied to the plurality of signal lines to each of the plurality of wirings (word line WL and the like) provided in the selected block BLK.

The sense amplifier module 45 is a sense circuit that senses the data read from the selected block BLK based on the voltage of the bit line BL in the read operation. The sense amplifier module 45 transmits the read data to the memory controller via the memory I/F 40. Further, the sense amplifier module 45 may apply a voltage corresponding to the data to be written to the memory cell for each bit line BL in the write operation.

### [4-1-2] Circuit Configuration of Memory Cell Array 42

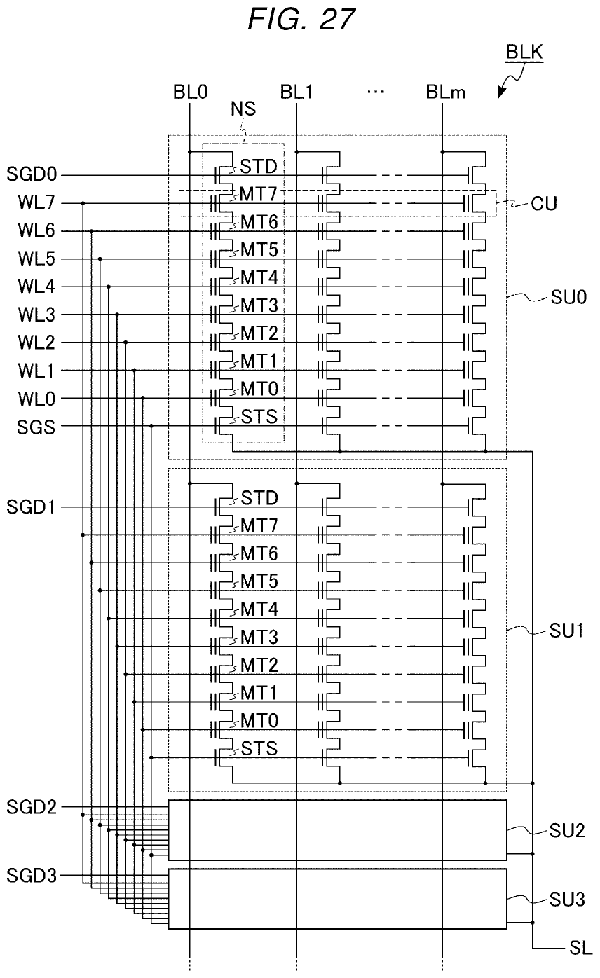

FIG. 27 is a circuit diagram showing an example of the circuit configuration of the memory cell array 42 provided in the memory device 4 according to the fourth embodiment. FIG. 27 shows one block BLK among a plurality of blocks BLK provided in the memory cell array 42. As shown in FIG. 27, the block BLK includes, for example, string units SU0 to SU3.

Each string unit SU includes a plurality of NAND strings NS. Each NAND string NS is associated with bit lines BL0 to BLm (where m is an integer equal to or larger than 1). Different column addresses are allocated to the respective bit lines BL0 to BLm. Each of the bit lines BL is shared by the NAND string NS to which the same column address is allocated among the plurality of blocks BLK. Each NAND string NS includes, for example, memory cell transistors MT0 to MT7 and select transistors STD and STS.

Each memory cell transistor MT includes a control gate and a charge storage layer, and stores data non-volatilely. The memory cell transistors MT0 to MT7 of each NAND string NS are connected in series. The control gates of the memory cell transistors MT0 to MT7 are connected to the word lines WL0 to WL7, respectively. Each of the word lines WL0 to WL7 is provided for each block BLK. A set of a plurality of memory cell transistors MT connected to a common word line WL in the same string unit SU is referred to as, for example, a “cell unit CU”. When each memory cell transistor MT stores 1-bit data, the cell unit CU stores “1 page data”. The cell unit CU may have a storage capacity equal to or larger than two page data according to the number of bits of data stored in the memory cell transistor MT.

Each of the select transistors STD and STS is used to select the string unit SU. The drain of the select transistor STD is connected to the associated bit line BL. The source of the select transistor STD is connected to one ends of the memory cell transistors MT0 to MT7 connected in series. The gates of the select transistors STD provided in the string units SU0 to SU3 are connected to the select gate lines SGD0 to SGD3, respectively. The drain of the select transistor STS is connected to the other ends of the memory cell transistors MT0 to MT7 connected in series. The source of the select transistor STS is connected to a source line SL. The gate of the select transistor STS is connected to the select gate line SGS. The source line SL is shared by, for example, the plurality of blocks BLK.

### [4-1-3] Structure of Memory Device 4

Hereinafter, an example of the structure of the memory device 4 according to the fourth embodiment will be described. In the fourth embodiment, the X direction corresponds to the extending direction of the word line WL, the Y direction corresponds to the extending direction of the bit line BL, and the Z direction corresponds to the direction perpendicular to the surface of the semiconductor substrate used for forming the memory device 4.

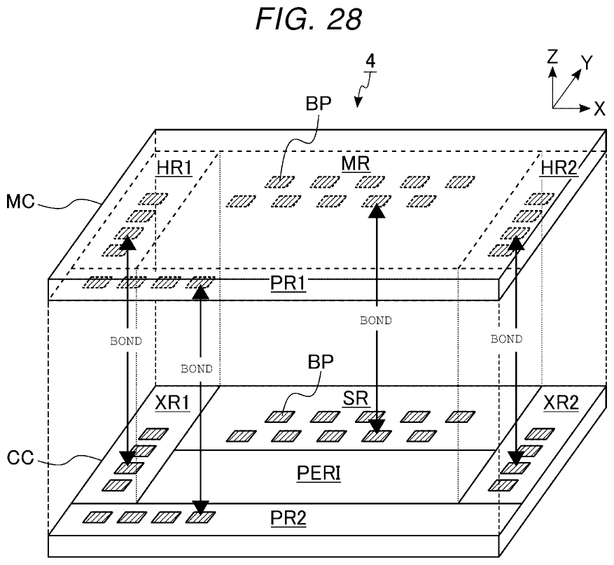

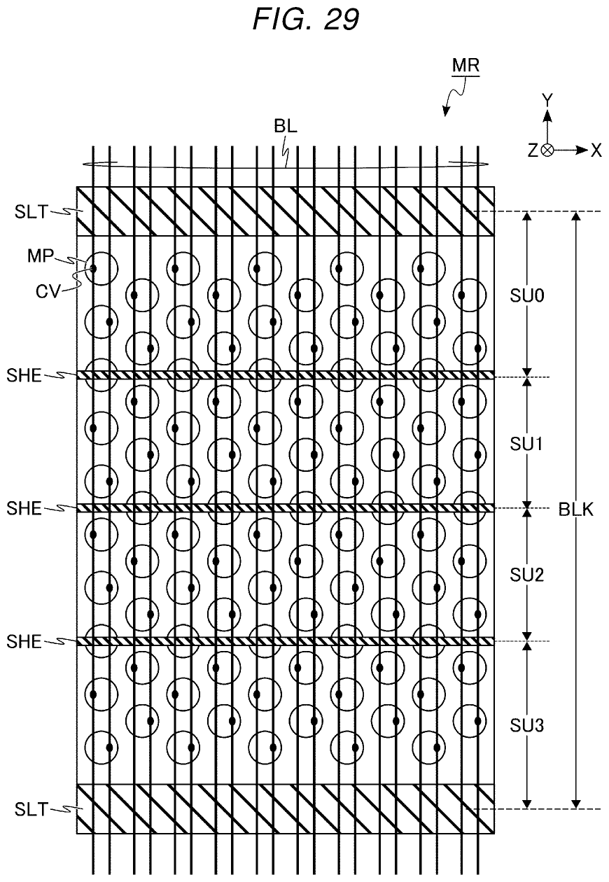

FIG. 28 is a perspective diagram showing an example of the structure of the memory device 4 according to the fourth embodiment. As shown in FIG. 28, the memory device 4 includes memory chips MC and CMOS chips CC. The lower surface of the memory chips MC corresponds to the primary surface of the lower wafer LW. The upper surface of the CMOS chips CC corresponds to the primary surface of the upper wafer UW. The memory chips MC include, for example, a memory region MR, extraction regions HR1 and HR2, and a pad region PR1. The CMOS chips CC include, for example, a sense amplifier region SR, a peripheral circuit region PERI, transmission regions XR1 and XR2, and a pad region PR2.

The memory region MR includes the memory cell array 42. The extraction regions HR1 and HR2 include wirings used for connection between stacked wirings provided in the memory chips MC and the row decoder module 44 provided in the CMOS chips CC. The pad region PR1 includes a pad or the like used for connecting the memory device 4 and the memory controller. The extraction regions HR1 and HR2 sandwich the memory region MR in the X direction. The pad region PR1 is adjacent to each of the memory region MR and the extraction regions HR1 and HR2 in the Y direction.

The sense amplifier region SR includes the sense amplifier module 45. The peripheral circuit region PERI includes the sequencer 41, the driver module 43, and the like. The transmission regions XR1 and XR2 include the row decoder module 44. The pad region PR2 includes the memory I/F 40. The sense amplifier region SR and the peripheral circuit region PERI are disposed adjacent to each other in the Y direction and overlap the memory region MR. The transmission regions XR1 and XR2 sandwich the set of the sense amplifier region SR and the peripheral circuit region PERI in the X direction, and overlap the extraction regions HR1 and HR2, respectively. The pad region PR2 overlaps the pad region PR1 of the memory chips MC.

The memory chips MC have a plurality of bonding pads BP under each of the memory region MR, the extraction regions HR1 and HR2, and the pad region PR1. The bonding pad BP of the memory region MR is connected to the associated bit line BL. The bonding pad BP of the extraction region HR is connected to the associated wiring (for example, the word line WL) among the stacked wirings provided in the memory region MR. The bonding pad BP of the pad region PR1 is connected to a pad provided on the upper surface of the memory chips MC. The pad provided on the upper surface of the memory chips MC is used, for example, for connections between the memory device 4 and the memory controller.

The CMOS chips CC have a plurality of bonding pad BPs on the upper part of each of the sense amplifier region SR, the peripheral circuit region PERI, the transmission regions XR1 and XR2, and the pad region PR2. The bonding pad BP of the sense amplifier region SR overlaps the bonding pad BP of the memory region MR. The bonding pad BP of the transmission regions XR1 and XR2 overlaps the bonding pad BP of the extraction regions HR1 and HR2, respectively. The bonding pad BP of the pad region PR1 overlaps the bonding pad BP of the pad region PR2.

The memory device 4 has a structure in which the lower surface of the memory chips MC and the upper surface of the CMOS chips CC are bonded. Among the plurality of bonding pads BP provided in the memory device 4, the two bonding pads BP facing each other between the memory chips MC and the CMOS chips CC are electrically connected by being bonded. As a result, circuits in the memory chips MC and circuits in the CMOS chips CC are electrically connected via the bonding pad BP. The set of two bonding pads BP facing each other between the memory chips MC and the CMOS chips CC may have a boundary or may be integrated. Plan Layout of Memory Cell Array 42

FIG. 29 is a plan diagram showing an example of the plan layout of the memory cell array 42 provided in the memory device 4 according to the fourth embodiment. FIG. 29 shows a region including one block BLK in the memory region MR. As shown in FIG. 29, the memory device 4 includes, for example, a plurality of slits SLT, a plurality of slits SHE, a plurality of memory pillars MP, a plurality of bit lines BL, and a plurality of contacts CV. In the memory region MR, the plan layout described below is repeatedly disposed in the Y direction.

Each of the slits SLT has, for example, a structure in which an insulating member is embedded. Each of the slits SLT insulates wirings (for example, word lines WL0 to WL7 and select gate lines SGD and SGS) adjacent to each other via the slit SLT. Each of the slits SLT has a portion that extends in the X direction and crosses the memory region MR and the extraction regions HR1 and HR2 along the X direction. The plurality of slits SLTs are arranged in the Y direction. A region separated by the slits SLT corresponds to the block BLK.

Each of the slits SHE has, for example, a structure in which an insulating member is embedded. Each of the slits SHE insulates wirings (at least the select gate line SGD) adjacent to each other via the slit SLT. Each of the slits SHE has a portion that extends in the X direction and crosses the memory region MR. The plurality of slits SHE are arranged in the Y direction. In this example, three slits SHE are disposed between adjacent slits SLT. The plurality of regions separated by the slits SLT and SHE correspond to the string units SU0 to SU3, respectively.

Each of the memory pillars MP functions as, for example, one NAND string NS. The plurality of memory pillars MP are disposed in a staggered pattern of, for example, 19 rows in the region between two adjacent slits SLT. Then, counting from the upper side of a paper surface, one slit SHE overlaps each of the memory pillar MP in a fifth row, the memory pillar MP in a tenth row, and the memory pillar MP in a fifteenth row.

Each of the bit lines BL has a portion that extends in the Y direction and crosses a region provided with a plurality of blocks BLK along the Y direction. The plurality of bit lines BL are arranged in the X direction. Each of the bit lines BL overlaps at least one memory pillar MP for each string unit SU. In this example, two bit lines BL overlap each memory pillar MP.

Each of the contacts CV is provided between one bit line BL among the plurality of bit lines BL overlapping the memory pillar MP and the memory pillar MP. The contact CV electrically connects the memory pillar MP and the bit line BL. The contact CV between the memory pillar MP overlapping the slit SHE and the bit line BL is omitted.

### Cross-sectional Structure of Memory Cell Array 42

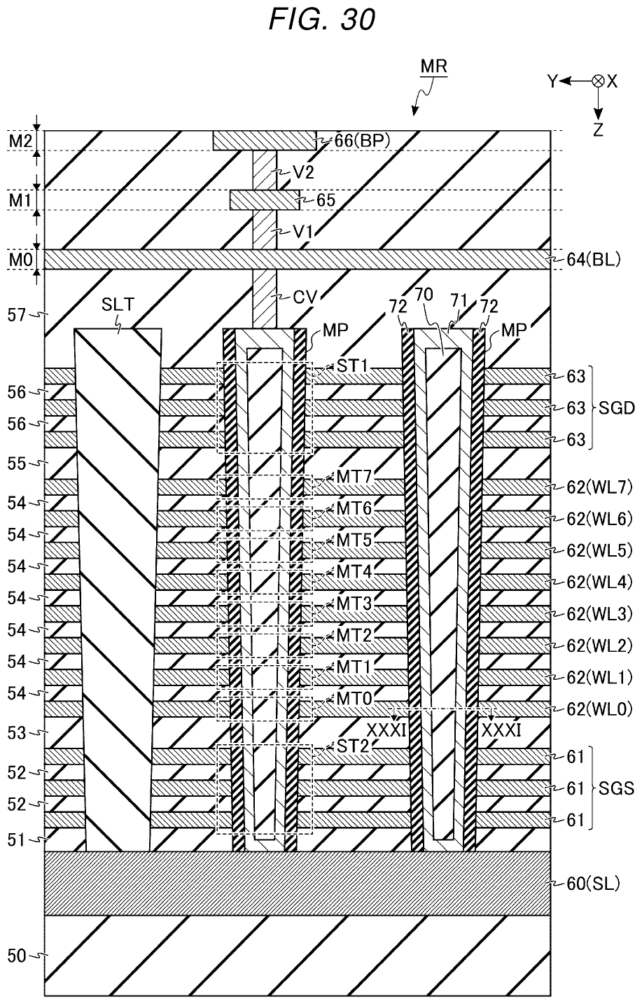

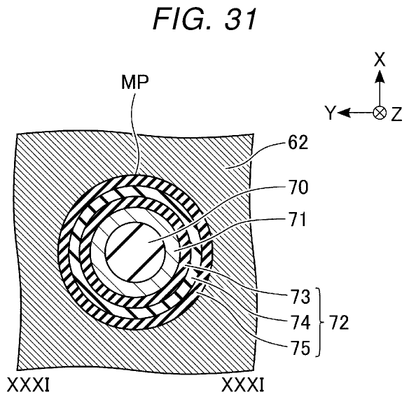

FIG. 30 is a cross-sectional diagram showing an example of a cross-sectional structure of the memory cell array 42 provided in the memory device 4 according to the fourth embodiment. FIG. 30 shows a cross section including the memory pillar MP and the slit SLT in the memory region MR along the Y direction. The Z direction in FIG. 30 indicates the lower side of the paper surface, but in the description of FIG. 30, the upper side of the paper surface is referred to as “above” and the lower side of the paper surface is referred to as “below”. As shown in FIG. 30, the memory device 4 includes, for example, insulator layers 50 to 57, conductor layers 60 to 66, and contacts V1 and V2.

The insulator layer 50 is provided, for example, on the bottom layer of the memory chips MC. The conductor layer 60 is provided on the insulator layer 50. The insulator layer 51 is provided on the conductor layer 60. The conductor layer 61 and the insulator layer 52 are alternately provided on the insulator layer 51. The insulator layer 53 is provided on the conductor layer 61 of a top layer. The conductor layer 62 and the insulator layer 54 are alternately provided on the insulator layer 53. The insulator layer 55 is provided on the conductor layer 62 of the top layer. The conductor layer 63 and the insulator layer 56 are alternately provided on the insulator layer 55. The insulator layer 57 is provided on the conductor layer 63 of the top layer. The conductor layer 64 is provided on the insulator layer 57. The contact V1 is provided on the conductor layer 64. The conductor layer 65 is provided on the contact V1. The contact V2 is provided on the conductor layer 65. The conductor layer 66 is provided on the contact V2. Hereinafter, wiring layers provided with the conductor layers 64, 65 and 66 are referred to as “M0”, “M1” and “M2”, respectively.

Each of the conductor layers 60, 61, 62 and 63 is formed, for example, in a plate shape extending along an XY plane. The conductor layer 64 is formed, for example, in a line shape extending in the Y direction. The conductor layers 60, 61 and 63 are used as the source line SL, the select gate line SGS, and the select gate line SGD, respectively. The plurality of conductor layers 62 are used as the word lines WL0 to WL7 in order from the side of the conductor layer 60, respectively. The conductor layer 64 is used as the bit line BL. The contacts V1 and V2 are provided in a columnar shape. The conductor layers 64 and 65 are connected via the contact V1. The conductor layer 65 and the conductor layer 66 are connected via the contact V2. The conductor layer 65 is, for example, a wiring formed in a line shape extending in the X direction. The conductor layer 66 is in contact with the interface of the memory chips MC to be used as the bonding pad BP. The conductor layer 66 contains, for example, copper.

The slit SLT has a portion formed in a plate shape extending along the XZ plane, and divides the insulator layers 51 to 56 and the conductor layers 61 to 63. Each of the memory pillars MP extends in the Z direction, and penetrates the insulator layers 51 to 56 and the conductor layers 61 to 63. Each of the memory pillars MP includes, for example, a core member 70, a semiconductor layer 71, and a stacked film 72. The core member 70 is an insulator that extends in the Z direction. The semiconductor layer 71 covers the core member 70. The lower portion of the semiconductor layer 71 is in contact with the conductor layer 60. The stacked film 72 covers the side surface of the semiconductor layer 71. The contact CV is provided on the semiconductor layer 71. The conductor layer 64 is in contact with the contact CV.

In the region shown in the drawing, the contact CV corresponding to one of the two memory pillars MP is shown. The contact CV is electrically connected to the memory pillar MP in a region which is not shown in the drawing. A portion at which the memory pillar MP and the plurality of conductor layers 61 intersect with each other functions as the select transistor STS. A portion at which the memory pillar MP and the conductor layer 62 intersect with each other functions as the memory cell transistor MT. A portion at which the memory pillar MP and the plurality of conductor layers 63 intersect with each other functions as the select transistor STD.

### Cross-Sectional Structure of Memory Pillar MP

FIG. 31 is a cross-sectional diagram taken along a line XXXI-XXXI of FIG. 30 showing an example of the cross-sectional structure of the memory pillar MP provided in the memory device 4 according to the fourth embodiment. FIG. 31 shows a cross section including the memory pillar MP and the conductor layer 62 and parallel to the conductor layer 60. As shown in FIG. 31, the stacked film 72 includes, for example, a tunnel insulating film 73, an insulating film 74, and a block insulating film 75.

The core member 70 is provided, for example, at the center of the memory pillar MP. The semiconductor layer 71 surrounds the side surface of the core member 70. The tunnel insulating film 73 surrounds the side surface of the semiconductor layer 71. The insulating film 74 surrounds the side surface of the tunnel insulating film 73. The block insulating film 75 surrounds the side surface of the insulating film 74. The conductor layer 62 surrounds the side surface of the block insulating film 75. The semiconductor layer 71 is used as a channel (current path) of the memory cell transistors MT0 to MT7 and the select transistors STD and STS. Each of the tunnel insulating film 73 and the block insulating film 75 contains, for example, silicon oxide. The insulating film 74 is used as a charge storage layer of the memory cell transistor MT, and contains, for example, silicon nitride. As a result, each of the memory pillars MP functions as one NAND string NS.

### Cross-Sectional Structure of Memory Device 4

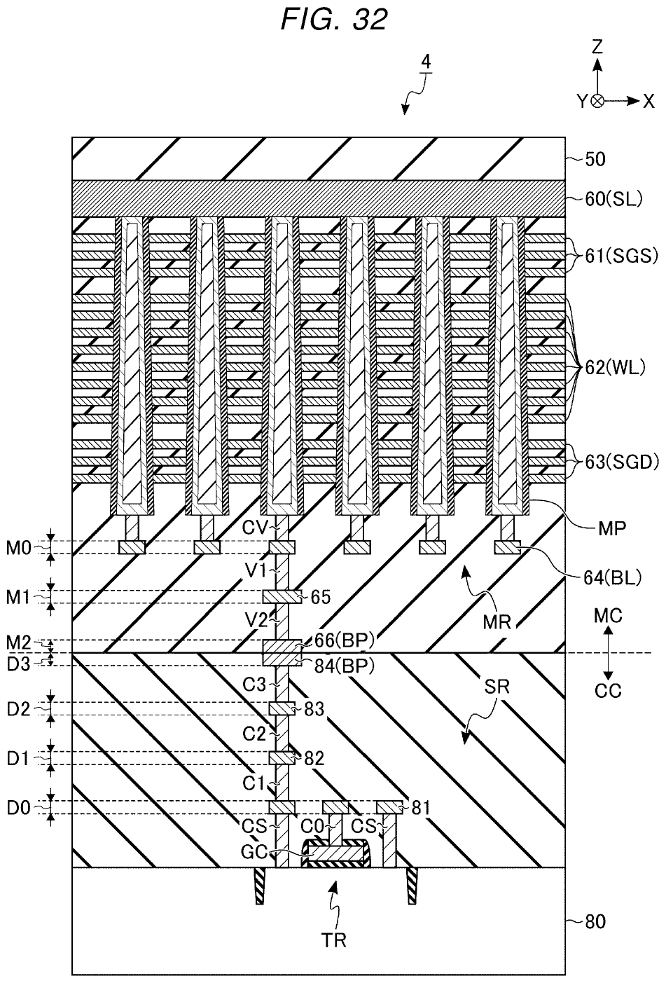

FIG. 32 is a cross-sectional diagram showing an example of the cross-sectional structure of the memory device 4 according to the fourth embodiment. FIG. 32 displays a cross section including the memory region MR and the sense amplifier region SR, that is, a cross section including the memory chips MC and the CMOS chips CC. As shown in FIG. 32, the memory device 4 includes a semiconductor substrate 80, conductor layers GC and 81 to 84, and contacts CS and C0 to C3 in the sense amplifier region SR.

The semiconductor substrate 80 is a substrate used for forming the CMOS chips CC. The semiconductor substrate 80 includes a plurality of well regions. For example, a transistor TR is formed in each of the plurality of well regions. The plurality of well regions are separated by, for example, Shallow Trench Isolation (STI) features. The conductor layer GC is provided on the semiconductor substrate 80 via a gate insulating film. The conductor layer GC in the sense amplifier region SR is used as a gate electrode of the transistor TR provided in the sense amplifier module 45. The contact C0 is provided on the conductor layer GC. Two contacts CS are provided on the semiconductor substrate 80 to correspond to the source and drain of the transistor TR.

The conductor layer 81 is provided on each of the contact CS and the contact C0. The contact C1 is provided on the conductor layer 81. The conductor layer 82 is provided on the contact C1. The conductor layers 81 and 82 are electrically connected via the contact C1. The contact C2 is provided on the conductor layer 82. The conductor layer 83 is provided on the contact C2. The conductor layers 82 and 83 are electrically connected via the contact C2. The contact C3 is provided on the conductor layer 83. The conductor layer 84 is provided on the contact C3. The conductor layers 83 and 84 are electrically connected via the contact C3. Hereinafter, wiring layers provided with the conductor layers 81 to 84 are referred to as “D0”, “D1”, “D2”, and “D3”, respectively.

The conductor layer 84 is in contact with the interface of the CMOS chips CC to be used as the bonding pad BP. The conductor layer 84 in the sense amplifier region SR is bonded to the opposing conductor layer 66 (that is, the bonding pad BP of the memory chips MC) in the memory region MR. Then, each conductor layer 84 in the sense amplifier region SR is electrically connected to one bit line BL. The conductor layer 84 contains, for example, copper.

In the memory device 4, the wiring layer D3 of the CMOS chips CC and the wiring layer M2 of the memory chips MC are adjacent to each other by bonding the memory chips MC and the CMOS chips CC. The semiconductor substrate 80 corresponds to the back surface side of the upper wafer UW, and the wiring layer D3 corresponds to the surface side of the upper wafer UW. The insulator layer 50 corresponds to the back surface side of the lower wafer LW, and the wiring layer M2 corresponds to the surface side of the lower wafer LW. The semiconductor substrate used to form the memory chips MC is removed in a step such as forming a pad after the bonding process.

### [4-2] Effect of Fourth Embodiment

As described above, the memory device 4 has, for example, the memory chips MC having a structure in which memory cells are three-dimensionally stacked, and CMOS chips CC including other control circuits and the like. In the memory chips MC and the CMOS chips CC, the memory chips MC tend to have a larger variation in wafer magnification between the wafers. Specifically, since the memory chips MC includes the high-rise memory cell array 42, the variation in the amount of warpage of the wafer is large, and the variation in the wafer magnification may be large. On the other hand, the disposition of the shots of the CMOS chips CC is close to an ideal grid based on the exposure device. Therefore, when the bonding process is executed, it is preferable that the wafer on which the memory chips MC are formed is allocated to the lower wafer LW capable of correcting the wafer magnification, and the wafer on which the CMOS chips CC are formed is allocated to the upper wafer UW. As a result, each of the first to third embodiments can improve the yield of the memory device 4.

For the wiring layer close to the bonding surface of the memory chips MC, the allowable range for superposition misalignment of the wiring layer M1 may be narrow. For example, the conductor layer 65 extending in the X direction is formed on the wiring layer M1. The contact V2 connected to the wiring layer M1 is formed to overlap the conductor layer 65. That is, the superposition in a step of forming the contact V2 has some margin in the X direction but has no margin in the Y direction. Therefore, it is preferable that the Y-oriented mode is used in the exposure process for forming the contact V2 in this example. As described above, by using the exposure device 1 according to the first embodiment at the time of manufacturing the memory device 4, the influence of the XY difference in the wafer magnification is reduced, so that the yield of the semiconductor device can be improved.

### [5] Others

The flowchart used to explain the various operations is merely an example. In addition to variation and modifications to the described operations, in some examples, process steps may be re-ordered, other processes may be added, or some process may be omitted. In the above examples, the case where the lower wafer LW placed (held) on the lower stage 230 is bonded by applying the alignment correction is illustrated, but the present disclosure is not limited thereto. The alignment correction in the bonding process may be applied to the upper wafer UW placed (held) on the upper stage 233, or may be applied to both the upper wafer UW held on the upper stage 233 and the lower stage 230 held on the lower wafer LW. In the present specification, instead of a CPU being incorporated as a control device or the like, a Micro Processing Unit (MPU), an Application Specific Integrated Circuit (ASIC), a Field-Programmable Gate Array (FPGA), or the like may be used. Further, each of the processes described in the embodiments as performed by execution of software or the like on a CPU may instead be realized by dedicated hardware or the like. Such processes may also be a mixture of processes executed according to software and processes executed by dedicated hardware.

In the present specification, used of the term “connection” generally indicates electrical connection, and does not exclude inclusion of another element in between “connected” elements. The “electrically connected” may be even via an insulator element as long as the operation is performed in substantially the same manner as without an intervening insulator element. The phrase “columnar shape” indicates a structure provided within the hole formed in a step of manufacturing. The phrase “plan view” corresponds to viewing an object in a direction perpendicular to the surface of the semiconductor substrate 80. A “region” may be associated with or defined relative to a region on a semiconductor substrate such that, for example, the memory region MR may be considered to be a region of, or on, semiconductor substrate 80. The bonding pad BP may be referred to as a “bonding metal”. The camera 144 of the exposure device 1 may be include an optical system (such as a microscope) and a light receiving sensor separately disposed. Each of the cameras 144, 232 and 235 may be referred to as the “measurement device,” and in general, an sensor or camera type may be used as long as a position of the alignment mark AM may be measured. In the present specification, “superposition misalignment” may also be referred to as “positional misalignment” and/or used interchangeably.

The configuration described in the fourth embodiment is merely an example, and the configuration of the memory device 4 is not limited thereto. The circuit configuration, planar layout, and cross-sectional structure of the memory device 4 may be appropriately changed depending on various design choices of the memory device 4. For example, in the fourth embodiment, the case where the memory chips MC are provided on the CMOS chips CC is illustrated, but the CMOS chips CC may be provided on the memory chips MC. The case where the memory chips MC are allocated to the lower wafer LW and the CMOS chips CC are allocated to the upper wafer UW is illustrated, but the memory chips MC may be allocated to the upper wafer UW and the CMOS chips CC may be allocated to the lower wafer LW. When the manufacturing method described in the first to third embodiments is applied, it is preferable that the wafer having a larger variation in wafer magnification among two wafers is allocated to the lower wafer LW. As a result, the superposition misalignment in the bonding process may be reduced, so that the occurrence of defects due to the superposition misalignment may be reduced.

### Other Examples

Additional example embodiments are described in the following.

### Example 1

A bonding device may comprise: a first stage for holding a first substrate; a second stage for holding a second substrate and configured to face the first stage; a first measurement device configured to measure a first alignment mark on the first substrate; a second measurement device configured to measure a second alignment mark on the second substrate; and a control device configured control at least one of the first and second stage to execute a bonding process. In such a bonding process, the first substrate can be bonded to the second substrate after an adjusting of the relative positions of the first stage and the second stage by the control device based on a measurement of the first alignment mark, a measurement of the second alignment mark, and a first correction formula associated with the first substrate.

### Example 2

In the bonding device according to Example 1, the first correction formula can be associated with a correction value for a magnification component in an exposure process of the first substrate and provide a relationship between measured coordinates of the first alignment mark and a measurement error between the measured coordinates and a central position of the first substrate. The control device may adjust the relative positions of the first stage and the second stage based on a numerical value obtained by adding a measurement error calculated using the first correction formula to the measurement of the first alignment mark.

### Example 3

In the bonding device according to Example 1, the first correction formula can be associated with an amount of warpage of the first substrate and provide a relationship between measured coordinates of the first alignment mark and a measurement error between the measured coordinates and a central position of the first substrate. The control device may adjust the relative positions of the first stage and the second stage based on a numerical value obtained by adding a measurement error calculated using the first correction formula to the measurement of the first alignment mark.

### Example 4

In the bonding device according to Example 1, the control device may adjust the relative positions of the first stage and the second stage based on a second correction formula associated with the second substrate.

### Example 5

In the bonding device according to Example 4, the second correction formula can be associated with a correction value of a magnification component in an exposure process of the second substrate and provide a relationship between measured coordinates of the second alignment mark and a measurement error between the measured coordinates and a central position of the second substrate. The control device may adjust the relative positions of the first stage and the second stage based on a numerical value obtained by adding a measurement error calculated using the second correction formula to the measurement of the second alignment mark.

### Example 6

In the bonding device according to Example 3, the second correction formula can be associated with an amount of warpage of the second substrate and provide a relationship between measured coordinates of the second alignment mark and a measurement error between the measured coordinates and a central position of the second substrate. The control device may adjust the relative positions of the first stage and the second stage based on a numerical value obtained by adding a measurement error calculated using the second correction formula to the measurement of the second alignment mark.

### Example 7

A method for manufacturing a semiconductor device may comprise: holding a first substrate on a first stage; holding a second substrate on a second stage facing the first stage; measuring a first alignment mark on the first substrate; measuring a second alignment mark on the second substrate; and bonding the first substrate to the second substrate after adjusting relative positions of the first stage and the second stage based on a measurement of the first alignment mark, a measurement of the second alignment mark, and a first correction formula associated with the first substrate.

### Example 8

In the method according to Example 7, the first correction formula can be associated with a correction value of a magnification component used in an exposure process of the first substrate and provides a relationship between measured coordinates of the first alignment mark and a measurement error between the measured coordinates and a central position of the first substrate. Adjustment of the relative positions of the first stage and the second stage can be based on a numerical value obtained by adding a measurement error calculated using the first correction formula to the measurement of the first alignment mark.

### Example 9

In the method according to Example 7, the first correction formula can be associated with an amount of warpage of the first substrate and provide a relationship between measured coordinates of the first alignment mark and a measurement error between the measured coordinates and a central position of the first substrate. A numerical value, which is obtained by adding a measurement error calculated using the first correction formula to the measurement result of the first alignment mark, can be used for adjustment of the relative positions of the first stage and the second stage.

### Example 10

In the method according to Example 7, the adjustment of the relative positions of the first stage and the second stage can be based on a second correction formula associated with the second substrate.

### Example 11

In the method according to Example 10, the second correction formula can be associated with a correction value of a magnification component used in an exposure process of the second substrate and provide a relationship between measured coordinates of the second alignment mark and a measurement error between the measured coordinates and a central position of the second substrate. A numerical value, which is obtained by adding a measurement error calculated using the second correction formula to the measurement result of the second alignment mark, can be used for the adjustment of the relative positions of the first stage and the second stage.

### Example 12

In the method according to Example 10, the second correction formula can be associated with an amount of warpage of the second substrate and provide a relationship between measured coordinates of the second alignment mark and a measurement error between the measured coordinates and a central position of the second substrate. A numerical value, which is obtained by adding a measurement error calculated using the second correction formula to the measurement result of the second alignment mark, can be used for the adjustment of the relative positions of the first stage and the second stage.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

1. An exposure device that exposes a substrate with illumination light via a projection optical system, the device comprising:
a stage to hold a substrate to be exposed;
a measurement device configured to measure positions of at least three alignment marks on the substrate; and
a control device configured to move the stage based on measured positions of the at least three alignment marks from the measurement device to adjust an exposure position with respect to the substrate, wherein
the control device is configured to:
calculate, based on the measured positions of the at least three alignment marks, a first correction coefficient corresponding to a positional misalignment of a magnification component in a first direction and a second correction coefficient corresponding to a positional misalignment of a magnification component in a second direction intersecting the first direction,
use the first correction coefficient to correct the positional misalignment of the magnification component in the first direction when a first setting is applied,
use a third correction coefficient based on the first correction coefficient to correct the positional misalignment of the magnification component in the second direction when the first setting is applied,
use a fourth correction coefficient based on the second correction coefficient to correct the positional misalignment of the magnification component in the first direction when a second setting is applied, and
use the second correction coefficient to correct the positional misalignment of the magnification component in the second direction when the second setting is applied.

2. The exposure device according to claim 1, wherein
the first setting includes setting value for a ratio of the first correction coefficient to the third correction coefficient, and
the second setting includes setting value for a ratio of the second correction coefficient to the fourth correction coefficient.

3. The exposure device according to claim 1, wherein the control device is further configured to:
calculate, based on the measured positions of the at least three alignment marks, a fifth correction coefficient corresponding to a positional misalignment of an orthogonality component in the first direction and a sixth correction coefficient corresponding to a positional misalignment of an orthogonality component in the second direction, based on the measurement results of the at least three alignment marks,
use the fifth correction coefficient to correct the positional misalignment of the orthogonality component in the first direction when the first setting is applied,
use a seventh correction coefficient based on the fifth correction coefficient to correct the positional misalignment of the orthogonality component in the second direction when the first setting is applied,
use an eighth correction coefficient based on the sixth correction coefficient to correct the positional misalignment of the orthogonality component in the first direction when the second setting is applied, and
use the sixth correction coefficient to correct the positional misalignment of the orthogonality component in the second direction when the second setting is applied.

4. The exposure device according to claim 3, wherein
the first setting includes setting value for a ratio of the fifth correction coefficient to the seventh correction coefficient, and
the second setting includes setting value for a ratio of the sixth correction coefficient to the eighth correction coefficient.

5. A method for manufacturing a semiconductor device, the method comprising:
measuring positions of at least three alignment marks on a substrate;
calculating, based the measured positions of the at least three alignment marks, a first correction coefficient corresponding to a positional misalignment of a magnification component in a first direction and a second correction coefficient corresponding to a positional misalignment of a magnification component in a second direction intersecting the first direction;
exposing the substrate by using the first correction coefficient to correct the positional misalignment of the magnification component in the first direction when a first setting is applied to an exposure process;
using a third correction coefficient based on the first correction coefficient to correct the positional misalignment of the magnification component in the second direction when the first setting is applied to the exposure process;
using a fourth correction coefficient based on the second correction coefficient to correct the positional misalignment of the magnification component in the first direction when a second setting is applied to the exposure process; and
using the second correction coefficient to correct the positional misalignment of the magnification component in the second direction when the second setting is applied to the exposure process.

6. The method according to claim 5, further comprising:
calculating, based the measured positions of the at least three alignment marks, a fifth correction coefficient corresponding to a positional misalignment of an orthogonality component in the first direction and a sixth correction coefficient corresponding to a positional misalignment of an orthogonality component in the second direction;
using the fifth correction coefficient to correct the positional misalignment of the orthogonality component in the first direction when the first setting is applied to the exposure process;
using a seventh correction coefficient based on the fifth correction coefficient to correct the positional misalignment of the orthogonality component in the second direction when the first setting is applied to the exposure process;
using an eighth correction coefficient based on the sixth correction coefficient to correct the positional misalignment of the orthogonality component in the first direction when the second setting is applied to the exposure process; and
using the sixth correction coefficient to correct the positional misalignment of the orthogonality component in the second direction when the second setting is applied to the exposure process.

7. A method for manufacturing a semiconductor device, the method comprising:
calculating a correction value of a positional misalignment of a magnification component for when a first substrate and a second substrate are bonded to each other, the correction value being calculated based on first information related to the first substrate and second information related to the second substrate;
deforming a first stage based on the calculated correction value and holding the first substrate on the deformed first stage;
holding the second substrate on a second stage facing the first stage; and
placing the first substrate and the second substrate in a facing arrangement using the first stage and the second stage and then bonding the first substrate and the second substrate.

8. The method according to claim 7, wherein
the first information is a correction value of a magnification component calculated based on results obtained by measuring at least three alignment marks of the first substrate in an exposure process of the first substrate, and
the second information is a correction value of a magnification component calculated based on results obtained by measuring at least three alignment marks of the second substrate in an exposure process of the second substrate.

9. The method according to claim 7, wherein
the first information is information indicating an amount of warpage of the first substrate, and
the second information is information indicating an amount of warpage of the second substrate.
